(19) United States
(12) Patent Application Publication
(10) Pub. No.: US 2024/0186237 A1
(43) Pub. Date: Jun. 6, 2024

(54) THREE-DIMENSIONAL MEMORY DEVICE WITH WORD LINE SIDE-CONTACT VIA STRUCTURES AND METHODS FOR FORMING THE SAME

(71) Applicant: SANDISK TECHNOLOGIES LLC, ADDISON, TX (US)

(72) Inventor: Masanori TSUTSUMI, Yokkaichi (JP)

(21) Appl. No.: 18/353,577

(22) Filed: Jul. 17, 2023

Related U.S. Application Data
(60) Provisional application No. 63/386,062, filed on Dec. 5, 2022.

(51) Int. Cl. H01L 23/522; H01L 23/528; H10B 41/10; H10B 41/27; H10B 41/35; H10B 41/40; H10B 43/10; H10B 43/27; H10B 43/35; H10B 43/40

(52) U.S. Cl. CPC H01L 23/5226; H01L 23/5283; H10B 41/10; H10B 41/27; H10B 41/35; H10B 41/40; H10B 43/10; H10B 43/27; H10B 43/35; H10B 43/40

(57) ABSTRACT

A memory device includes at least one alternating stack of insulating layers and electrically conductive layers, memory openings vertically extending through each layer within the at least one alternating stack, memory opening fill structures located in the memory openings and containing a respective vertical semiconductor channel and a respective vertical stack of memory elements, and an electrically conductive side-contact via structure vertically extending through each layer within the at least one alternating stack and contacting a sidewall of one of the electrically conductive layers.

### FIELD

The present disclosure relates generally to the field of semiconductor devices, and particularly to a three-dimensional memory device including word line side-contact via structures and methods for forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device comprises at least one alternating stack of insulating layers and electrically conductive layers; memory openings vertically extending through each layer within the at least one alternating stack; memory opening fill structures located in the memory openings and comprising a respective vertical semiconductor channel and a respective vertical stack of memory elements; and an electrically conductive side-contact via structure vertically extending through each layer within the at least one alternating stack and contacting a sidewall of one of the electrically conductive layers.

According to another aspect of the present disclosure, a method of forming a memory device comprises forming at least one alternating stack of insulating layers and sacrificial material layers over a substrate; forming memory openings through the at least one alternating stack; forming memory opening fill structures in the memory openings, wherein each of the memory opening fill structures comprises a respective vertical stack of memory elements; forming a combination of a contact opening and a vertical stack of annular dielectric spacers through the at least one alternating stack, wherein the vertical stack of annular dielectric spacers comprises an annular sacrificial spacer located adjacent to a first one of the sacrificial material layers, at least one upper annular dielectric spacer overlying the annular sacrificial spacer, and at least one lower annular dielectric spacer underlying the annular sacrificial spacer; replacing the sacrificial material layers with electrically conductive layers; removing the annular sacrificial spacer and inner portions of the annular dielectric spacers around the contact opening, wherein a cylindrical sidewall of a first electrically conductive layer is physically exposed in the contact opening; and forming a side-contact via structure in the contact opening in contact with the cylindrical sidewall of the first electrically conductive layer, wherein the side-contact via structure is laterally spaced from and is electrically isolated from a remainder of the electrically conductive layers other than the first electrically conductive layer by remaining portions of the vertical stack of annular dielectric spacers.

### BRIEF DESCRIPTION OF THE DRAWINGS

FIG. 1A is a vertical cross-sectional view of a first exemplary structure for forming a semiconductor die after formation of optional semiconductor devices, optional lower level dielectric layers, optional lower metal interconnect structures, and in-process source-level material layers according to the first embodiment of the present disclosure.

FIG. 1B is a magnified schematic vertical cross-sectional view of a region of the first exemplary semiconductor die along the vertical plane C-C′ of FIG. 1B.

FIG. 2 is a vertical cross-sectional view of the first exemplary structure after formation of a vertically alternating sequence of continuous insulating layers and continuous sacrificial material layers according to the first embodiment of the present disclosure.

FIG. 3A is a vertical cross-sectional view of the first exemplary structure after formation of memory openings according to the first embodiment of the present disclosure.

FIG. 3B is a top-down view of the first exemplary structure of FIG. 3A. The hinged vertical plane A-A′ is a plane of the vertical cross-sectional view of FIG. 3A.

FIGS. 4A-4D are sequential vertical cross-sectional views of the a memory region during formation of a memory opening fill structure according to the first embodiment of the present disclosure.

FIG. 5 is a vertical cross-sectional view of the first exemplary structure after formation of memory opening fill structures according to the first embodiment of the present disclosure.

FIG. 6A is a vertical cross-sectional view of the first exemplary structure after formation of a patterned hard mask layer according to the first embodiment of the present disclosure.

FIG. 6B is a top-down view of the first exemplary structure of FIG. 6A. The hinged vertical plane A-A′ is a plane of the vertical cross-sectional view of FIG. 6A.

FIGS. 7A-7K are sequential vertical cross-sectional view of a contact region during formation of in-process layer contact assemblies according to the first embodiment of the present disclosure.

FIG. 8 is a vertical cross-sectional view of the first exemplary structure after formation of in-process layer contact assemblies and a contact-level dielectric layer according to the first embodiment of the present disclosure.

FIG. 9A is a vertical cross-sectional view of the first exemplary structure after formation of backside trenches according to the first embodiment of the present disclosure.

FIG. 9B is a top-down view of the first exemplary structure of FIG. 9A. The hinged vertical plane A-A′ is a plane of the vertical cross-sectional view of FIG. 9A.

FIGS. 10A-10E are sequential vertical cross-sectional views of a region of the first exemplary structure during replacement of a source-level sacrificial layer with a source contact layer according to the first embodiment of the present disclosure.

FIG. 11 is a vertical cross-sectional view of the first exemplary structure after formation of the source-level material layers according to the first embodiment of the present disclosure.

FIG. 12A is a vertical cross-sectional view of the first exemplary structure after formation of backside recesses according to the first embodiment of the present disclosure.

FIG. 12B is a magnified vertical cross-sectional view of a memory array region of the first exemplary structure of FIG. 12A.

FIG. 12C is a magnified vertical cross-sectional view of a contact region of the first exemplary structure of FIG. 12A.

FIG. 13A is a vertical cross-sectional view of the first exemplary structure after formation of electrically conductive layers according to the first embodiment of the present disclosure.

FIG. 13B is a magnified vertical cross-sectional view of a memory array region of the first exemplary structure of FIG. 13A.

FIG. 13C is a magnified vertical cross-sectional view of a contact region of the first exemplary structure of FIG. 13A.

FIG. 14A is a vertical cross-sectional view of the first exemplary structure after formation of backside trench fill structures according to the first embodiment of the present disclosure.

FIG. 14B is a magnified vertical cross-sectional view of a memory array region of the first exemplary structure of FIG. 14A.

FIGS. 15A-15D are sequential vertical cross-sectional views of the contact region during replacement of the in-process layer contact assemblies with layer contact assemblies according to the first embodiment of the present disclosure.

FIG. 16A is a vertical cross-sectional view of the first exemplary structure after formation of drain contact via structures according to the first embodiment of the present disclosure.

FIG. 16B is a top-down view of the first exemplary structure of FIG. 16A. The hinged vertical plane A-A′ is a plane of the vertical cross-sectional view of FIG. 16A.

FIG. 16C is a horizontal cross-sectional view of a contact region along horizontal plane C-C′ in FIG. 16A of the first exemplary structure according to the first embodiment of the present disclosure.

FIG. 16D is a plan view of a first alternative configuration of the first exemplary structure according to the first embodiment of the present disclosure.

FIG. 16E is a horizontal cross-sectional view of a contact region of the first alternative configuration of the first exemplary structure according to the first embodiment of the present disclosure.

FIG. 17 is a vertical cross-sectional view of the first exemplary structure after formation of upper metal interconnect structures and upper dielectric material layers according to the first embodiment of the present disclosure.

FIG. 18 is a vertical cross-sectional view of a second exemplary structure after formation of first-tier in-process layer contact assemblies according to a second embodiment of the present disclosure.

FIG. 19 is a vertical cross-sectional view of the second exemplary structure after formation of second-tier in-process layer contact assemblies according to the second embodiment of the present disclosure.

FIG. 20 is a vertical cross-sectional view of the second exemplary structure after formation of third-tier in-process layer contact assemblies according to the second embodiment of the present disclosure.

FIG. 21 is a vertical cross-sectional view of the second exemplary structure after formation of layer contact assemblies according to the second embodiment of the present disclosure.

### DETAILED DESCRIPTION

As discussed above, the embodiments of the present disclosure are directed to a three-dimensional memory device including word line side-contact via structures and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁵ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

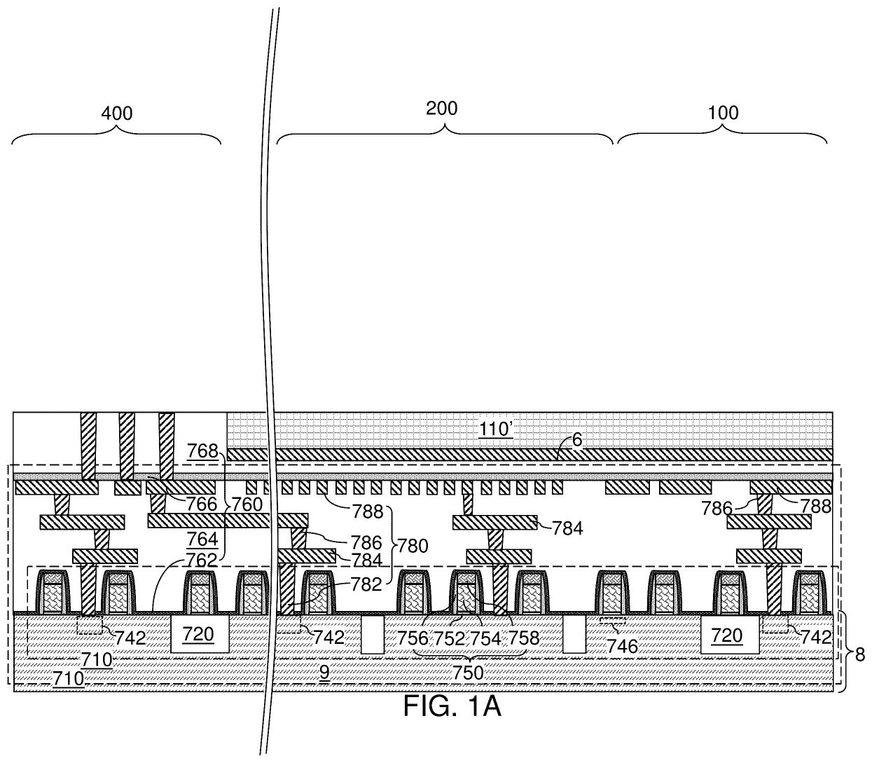

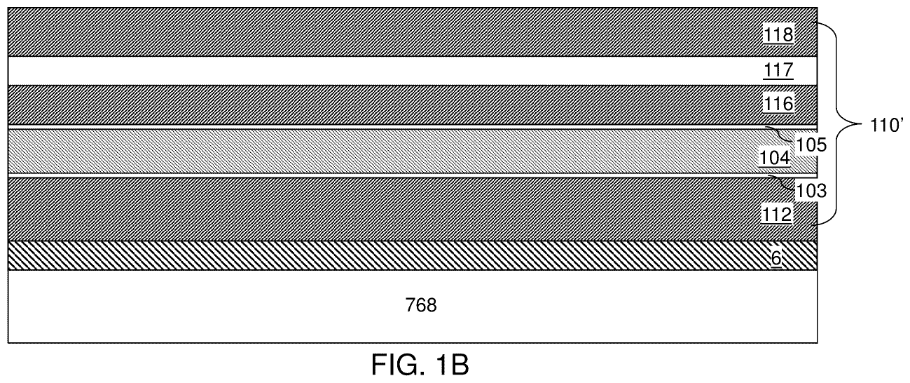

Referring to FIGS. 1A and 1B, a first exemplary structure according to a first embodiment of the present disclosure is illustrated. The first exemplary structure includes a semiconductor substrate 8 and a peripheral circuitry 710 formed thereupon. The first exemplary structure includes a memory array region 100 in which a three-dimensional memory array is to be subsequently formed, a contact region 200 in which contact via structures are to be subsequently formed, and a connection region 400 in which connection via structures are to be subsequently formed.

The semiconductor substrate 8 includes a substrate semiconductor layer 9 at least at an upper portion thereof. Various doped wells can be formed in upper portions of the substrate semiconductor layer 9. Shallow trench isolation structures 720 can be formed in an upper portion of the substrate semiconductor layer 9 to provide electrical isolation among the semiconductor devices. The peripheral circuitry 710 includes field effect transistors including respective transistor active regions 742 (i.e., source regions and drain regions), channel regions 746, and gate structures 750. The field effect transistors may be arranged in a CMOS configuration. Each gate structure 750 can include, for example, a gate dielectric 752, a gate electrode 754, a dielectric gate spacer 756 and a gate cap dielectric 758.

The peripheral circuitry 710 can include additional semiconductor devices in addition to p-type field effect transistors and n-type field effect transistors, which can be employed to support operation of a memory structure to be subsequently formed. The peripheral circuitry 710 includes a driver circuitry, which is also referred to as a peripheral circuitry. As used herein, a peripheral circuitry refers to any, each, or all, of word line decoder circuitry, word line switching circuitry, bit line decoder circuitry, bit line sensing and/or switching circuitry, power supply/distribution circuitry, data buffer and/or latch, or any other semiconductor circuitry that can be implemented outside a memory array structure for a memory device. For example, the semiconductor devices can include word line switching devices for electrically biasing word lines of three-dimensional memory structures to be subsequently formed.

Dielectric material layers are formed over the semiconductor devices, which are herein referred to as lower-level dielectric layers 760. The lower-level dielectric layers 760 can include, for example, a dielectric liner 762 (such as a silicon nitride liner that blocks diffusion of mobile ions and/or apply appropriate stress to underlying structures), first dielectric material layers 764 that overlie the dielectric liner 762, a silicon nitride layer (e.g., hydrogen diffusion barrier) 766 that overlies the first dielectric material layers 764, and at least one second dielectric layer 768.

The dielectric layer stack including the lower-level dielectric layers 760 functions as a matrix for lower-level metal interconnect structures 780 that provide electrical wiring among the various nodes of the semiconductor devices and landing pads for through-memory-level contact via structures to be subsequently formed. The lower-level metal interconnect structures 780 are embedded within the dielectric layer stack of the lower-level dielectric layers 760, and comprise a lower-level metal line structure located under and optionally contacting a bottom surface of the silicon nitride layer 766.

For example, the lower-level metal interconnect structures 780 can be embedded within the first dielectric material layers 764. The first dielectric material layers 764 may be a plurality of dielectric material layers in which various elements of the lower-level metal interconnect structures 780 are sequentially embedded. Each dielectric material layer among the first dielectric material layers 764 may include any of doped silicate glass, undoped silicate glass, organosilicate glass, silicon nitride, silicon oxynitride, and dielectric metal oxides (such as aluminum oxide). In one embodiment, the first dielectric material layers 764 can comprise, or consist essentially of, dielectric material layers having dielectric constants that do not exceed the dielectric constant of undoped silicate glass (silicon oxide) of 3.9. The lower-level metal interconnect structures 780 can include various device contact via structures 782 (e.g., source and drain electrodes which contact the respective source and drain nodes of the device or gate electrode contacts), intermediate lower-level metal line structures 784, lower-level metal via structures 786 and landing pads 788 for through-memory-level contact via structures to be subsequently formed.

The at least one second dielectric material layer 768 may include a single dielectric material layer or a plurality of dielectric material layers. Each dielectric material layer selected from the at least one second dielectric material layer 768 may include any of doped silicate glass, undoped silicate glass, and organosilicate glass. In one embodiment, the at least one second dielectric material layer 768 can comprise, or consist essentially of, dielectric material layers having dielectric constants that do not exceed the dielectric constant of undoped silicate glass (silicon oxide) of 3.9.

The peripheral circuitry 710 can include peripheral devices for the memory-level assembly to be subsequently formed. The lower-level metal interconnect structures 780 are embedded in the lower-level dielectric layers 760. The combination of the lower-level dielectric layers 760 and the lower-level metal interconnect structures 780 overlie the peripheral circuitry 710.

The lower-level metal interconnect structures 780 can be electrically connected to active nodes (e.g., transistor active regions 742 or gate electrodes 754) of the peripheral circuitry 710 (e.g., CMOS devices), and are located at the level of the lower-level dielectric layers 760. Through-memory-level contact via structures can be subsequently formed directly on the lower-level metal interconnect structures 780 to provide electrical connection to memory devices to be subsequently formed. Generally, lower-level metal interconnect structures 780 can be embedded within lower-level dielectric layers 760, and can be electrically connected to the peripheral circuitry 710.

An optional electrically conductive plate 6 and in-process source-level material layers 110′ including a layer stack of material layers can be formed over lower-level dielectric layers 760. The in-process source-level material layers 110′ can include various layers that are subsequently modified to form source-level material layers. The source-level material layers, upon formation, include a source contact layer that functions as a common source region for vertical field effect transistors of a three-dimensional memory device. In one embodiment, the in-process source-level material layer 110′ can include, from bottom to top, a lower source-level material layer 112, a lower sacrificial liner 103, a source-level sacrificial layer 104, an upper sacrificial liner 105, an upper source-level material layer 116, a source-level insulating layer 117, and an optional source-select-level conductive layer 118.

The lower source-level material layer 112 and the upper source-level material layer 116 can include a doped semiconductor material such as doped polysilicon or doped amorphous silicon. The doped semiconductor material of the lower source-level material layer 112 is herein referred to as a first doped semiconductor material, and the doped semiconductor material of the upper source-level material layer 116 is herein referred to as a second doped semiconductor material, which may be the same or different from the first doped semiconductor material. The conductivity type of the lower source-level material layer 112 and the upper source-level material layer 116 can be the opposite of the conductivity of vertical semiconductor channels to be subsequently formed. For example, if the vertical semiconductor channels to be subsequently formed have a doping of a first conductivity type, the lower source-level material layer 112 and the upper source-level material layer 116 have a doping of a second conductivity type that is the opposite of the first conductivity type. The thickness of each of the lower source-level material layer 112 and the upper source-level material layer 116 can be in a range from 10 nm to 300 nm, such as from 20 nm to 150 nm, although lesser and greater thicknesses can also be employed.

The source-level sacrificial layer 104 includes a sacrificial material that can be removed selective to the lower sacrificial liner 103 and the upper sacrificial liner 105. In one embodiment, the source-level sacrificial layer 104 can include a dielectric material such as silicon nitride, or a semiconductor material such as undoped amorphous silicon or polysilicon. The thickness of the source-level sacrificial layer 104 can be in a range from 30 nm to 400 nm, such as from 60 nm to 200 nm, although lesser and greater thicknesses can also be employed.

The lower sacrificial liner 103 and the upper sacrificial liner 105 include materials that can function as an etch stop material during removal of the source-level sacrificial layer 104. For example, the lower sacrificial liner 103 and the upper sacrificial liner 105 can include silicon oxide, silicon nitride, and/or a dielectric metal oxide. In one embodiment, each of the lower sacrificial liner 103 and the upper sacrificial liner 105 can include a silicon oxide layer having a thickness in a range from 2 nm to 30 nm, although lesser and greater thicknesses can also be employed.

The source-level insulating layer 117 includes a dielectric material such as silicon oxide. The thickness of the source-level insulating layer 117 can be in a range from 20 nm to 400 nm, such as from 40 nm to 200 nm, although lesser and greater thicknesses can also be employed. The optional source-select-level conductive layer 118 can include a conductive material that can be employed as a source-select-level gate electrode. For example, the optional source-select-level conductive layer 118 can include a heavily doped semiconductor material such as doped polysilicon or doped amorphous silicon that can be subsequently converted into doped polysilicon by an anneal process. The thickness of the optional source-level conductive layer 118 can be in a range from 30 nm to 200 nm, such as from 60 nm to 100 nm, although lesser and greater thicknesses can also be employed.

The in-process source-level material layers 110′ can be formed directly above a subset of the semiconductor devices on the semiconductor substrate 8 (e.g., silicon wafer). As used herein, a first element is located “directly above” a second element if the first element is located above a horizontal plane including a topmost surface of the second element and an area of the first element and an area of the second element has an areal overlap in a plan view (i.e., along a vertical plane or direction perpendicular to the top surface of the substrate 8.

The in-process source-level material layers 110′ may be patterned to provide openings in areas in which through-memory-level contact via structures and through-dielectric contact via structures are to be subsequently formed. Patterned portions of the in-process source-level material layers 110′ are present in each memory array region 100 in which three-dimensional memory stack structures are to be subsequently formed. The at least one second dielectric material layer 768 can include a blanket layer portion underlying the in-process source-level material layers 110′ and a patterned portion that fills gaps among the patterned portions of the in-process source-level material layers 110′.

The in-process source-level material layers 110′ can be patterned such that an opening extends over a contact region 200 in which contact via structures contacting word line electrically conductive layers are to be subsequently formed. In one embodiment, the contact region 200 can be laterally spaced from the memory array region 100 along a first horizontal direction hd1. A horizontal direction that is perpendicular to the first horizontal direction hd1 is herein referred to as a second horizontal direction hd2.

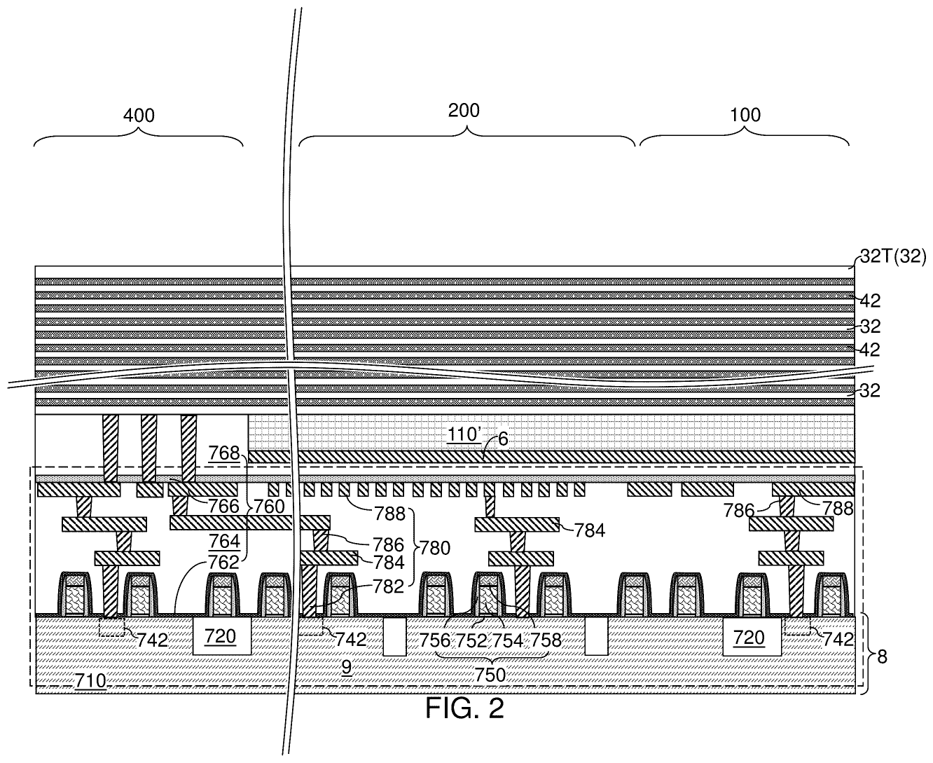

Referring to FIG. 2, at least one alternating stack of insulating layers 32 and spacer material layers can be formed over the in-process source-level material layers 110′. The spacer material layers may be formed as sacrificial material layers 42 that are subsequently replaced with electrically conductive layers, or may be formed as electrically conductive layers. While embodiments in which sacrificial material layers 42 are employed to form at least one alternating stack (32, 42) are described, other embodiments are expressly contemplated herein in which the spacer material layers are formed as electrically conductive layers (thereby obviating the need to perform replacement processes).

Each insulating layer 32 can include an insulating material, and each sacrificial material layer 42 can include a sacrificial material. An alternating plurality of insulating layers 32 and sacrificial material layers 42 is formed over the in-process source-level material layers. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness thereamongst, or may have different thicknesses. The second elements may have the same thickness thereamongst, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

Insulating materials that can be employed for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The sacrificial material of the sacrificial material layers 42 comprises a material can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise an insulating material, a semiconductor material, or a conductive material. The second material of the sacrificial material layers 42 can be subsequently replaced with electrically conductive electrodes which can function, for example, as control gate electrodes of a vertical NAND device. In one embodiment, the sacrificial material layers 42 can be material layers that comprise silicon nitride.

In one embodiment, the insulating layers 32 can include silicon oxide, and sacrificial material layers can include silicon nitride sacrificial material layers. The first material of the insulating layers 32 can be deposited, for example, by chemical vapor deposition (CVD). For example, if silicon oxide is employed for the insulating layers 32, tetraethylorthosilicate (TEOS) can be employed as the precursor material for the CVD process. The second material of the sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be employed for each insulating layer 32 and for each sacrificial material layer 42. The number of repetitions of the pairs of a insulating layer 32 and a sacrificial material layer 42 can be in a range from 2 to 1,024, and typically from 8 to 256, although a greater number of repetitions can also be employed. In one embodiment, each sacrificial material layer 42 in the vertically alternating sequence (32, 42) can have a uniform thickness that is substantially invariant within each respective sacrificial material layer 42. The topmost layer among the insulating layers 32 is herein referred to as a topmost insulating layer 32T.

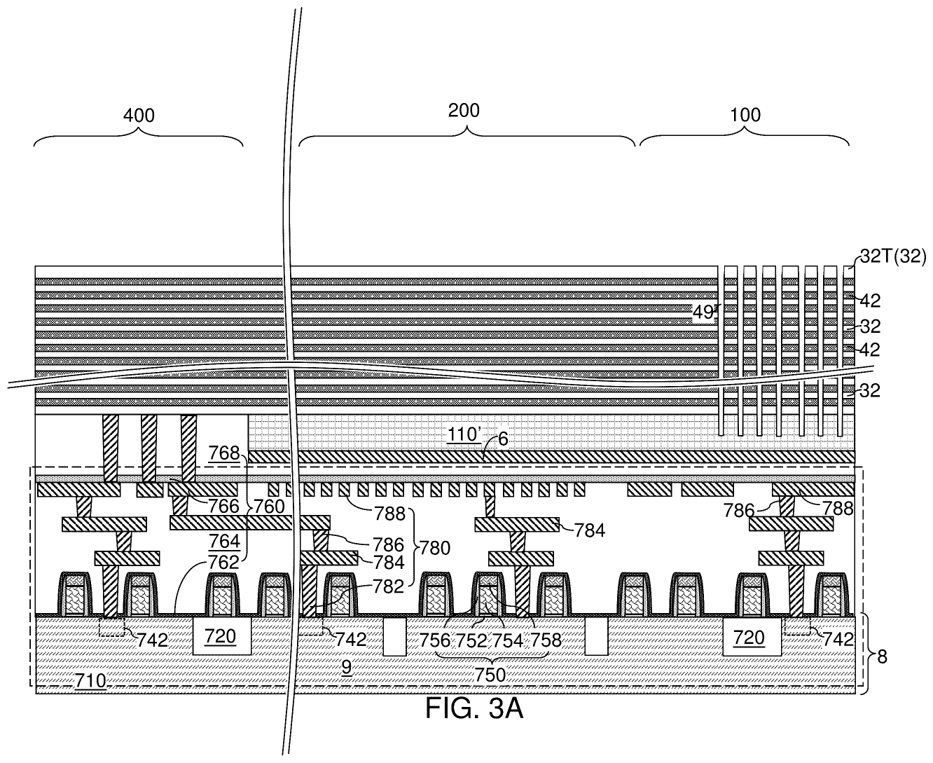

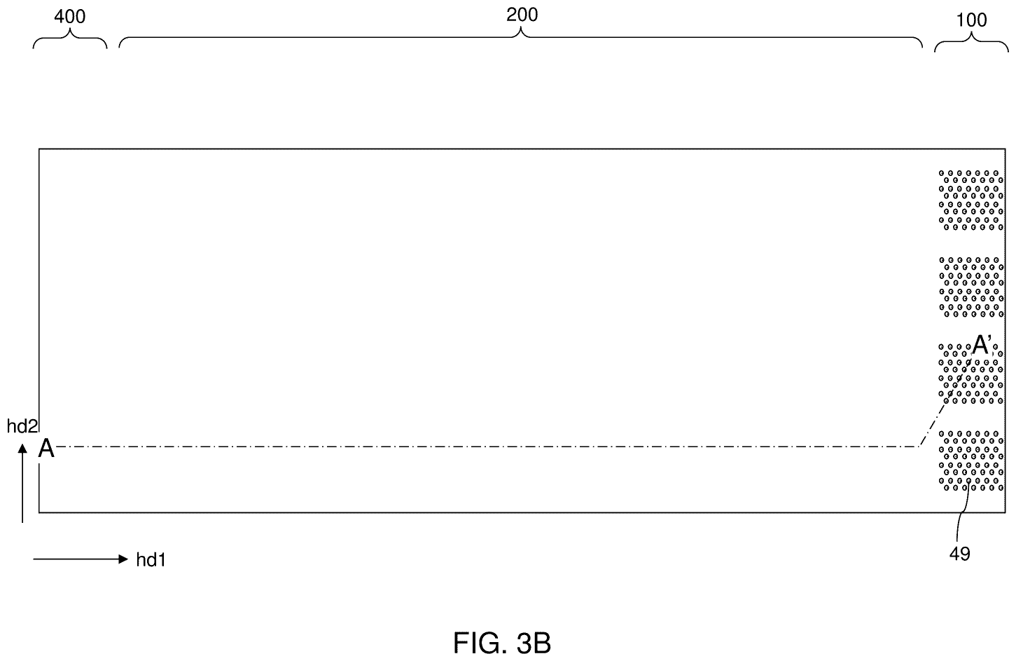

Referring to FIGS. 3A and 3B, memory openings 49 can be formed through the alternating stack (32, 42) and partly through the in-process source-level material layers 110′. For example, a photoresist layer (not shown) can be applied over the alternating stack (32, 42), and can be lithographically patterned to form arrays of discrete openings therethrough. The pattern of openings in the photoresist layer can be transferred through the alternating stack (32, 42) and partly through the in-process source-level material layers 110′ by an anisotropic etch process to form the memory openings 49.

The memory openings 49 are openings that are formed in the memory array region 100 through each layer within the first alternating stack (32, 42) and are subsequently employed to form memory stack structures therein. The bottom surfaces of the memory openings 49 can be recessed surfaces of the lower source-level semiconductor layer 112. Thus, each memory opening 49 can be formed through the source-level sacrificial layer 104, and may have a bottom surface between a horizontal plane including the bottom surface of the lower source-level semiconductor layer 112 and a horizontal plane including the top surface of the lower source-level semiconductor layer 112.

In one embodiment, the memory openings 49 can be formed as clusters that are laterally spaced apart from each other along the second horizontal direction hd2. Each cluster of memory openings 49 can include a respective two-dimensional array of memory openings 49 having a first pitch along one horizontal direction and a second pitch along another horizontal direction. In one embodiment, the direction of the first memory structure pitch can be the first horizontal direction (e.g., word line direction) hd1 and the direction of the second memory structure pitch can be the second horizontal direction (e.g., bit line direction) hd2, or vice versa.

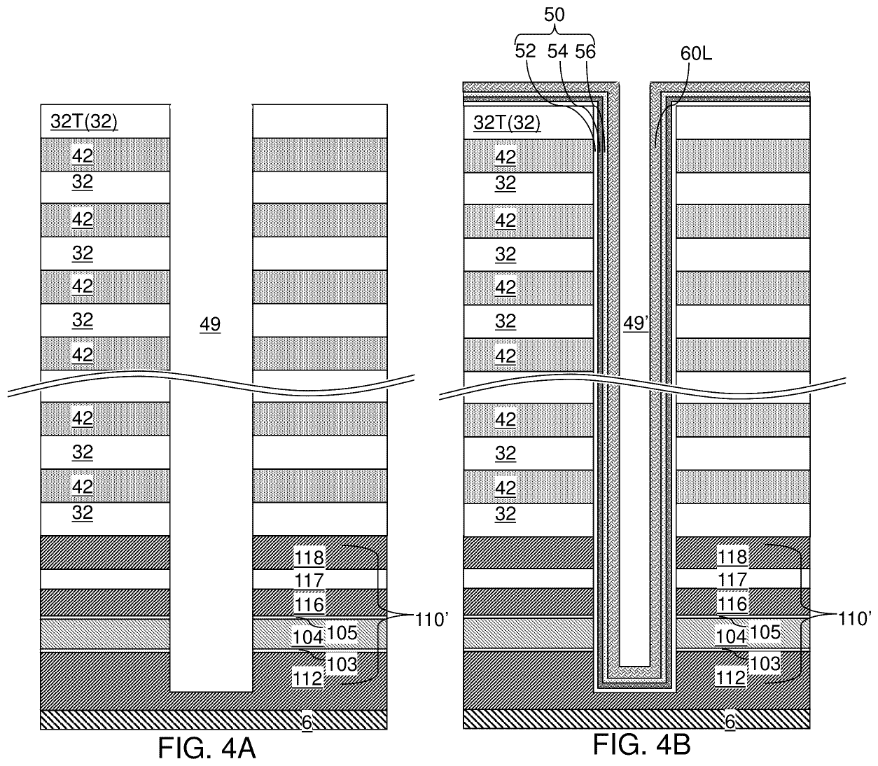

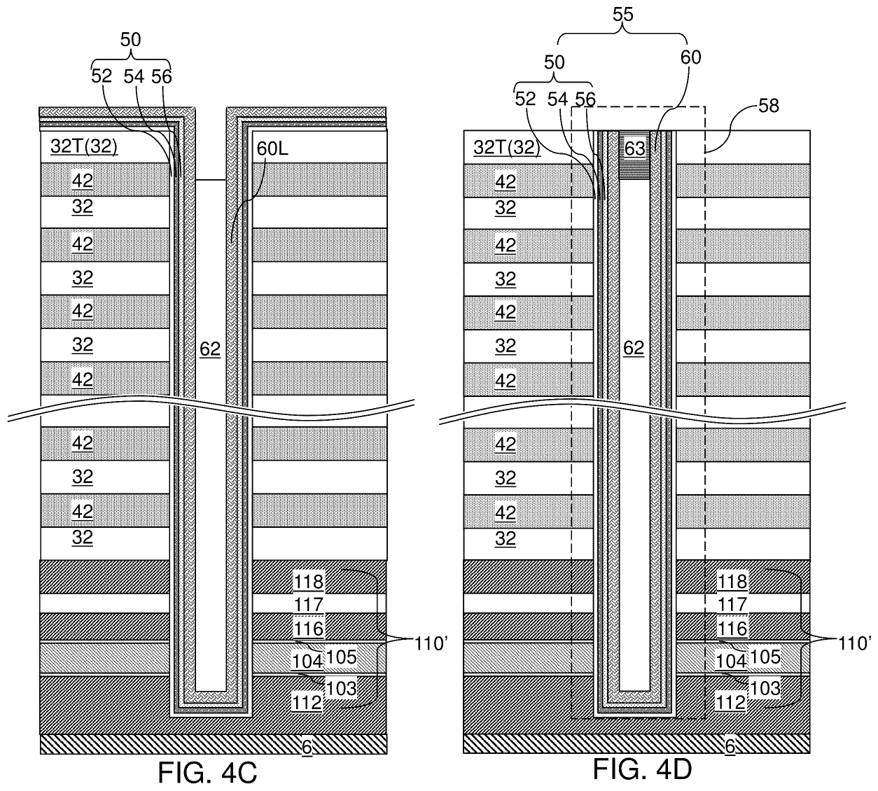

FIGS. 4A-4D provide sequential cross-sectional views of a memory opening 49 during formation of a memory opening fill structure 58. The same structural change occurs in each memory openings 49.

Referring to FIG. 4A, a memory opening 49 in the first exemplary device structure of FIGS. 3A and 3B is illustrated.

Referring to FIG. 4B, a stack of layers including a blocking dielectric layer 52, a memory material layer 54, an optional dielectric liner 56, and a semiconductor channel material layer 60L can be sequentially deposited in the memory openings 49. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

In another embodiment, the sacrificial material layers 42 can be laterally recessed with respect to the sidewalls of the insulating layers 32, and a combination of a deposition process and an anisotropic etch process can be employed to form the memory material layer 54 as a plurality of memory material portions that are vertically spaced apart. While an embodiment is described in which the memory material layer 54 is a single continuous layer, embodiments are expressly contemplated herein in which the memory material layer 54 is replaced with a plurality of memory material portions (which can be charge trapping material portions or electrically isolated conductive material portions) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

Generally, any vertical stack of memory elements known in the art may replace the memory material layer 54. The vertical stack of memory elements can be formed at levels of the sacrificial material layers 42 within each memory opening 49, and may be formed as portions of a continuous memory material layer, or may be formed as discrete memory material portions.

The optional dielectric liner 56, if present, includes a dielectric material. In one embodiment, the optional dielectric liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The optional dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the optional dielectric liner 56 can include a stack of a first silicon oxide layer, a silicon oxynitride layer, and a second silicon oxide layer, which is commonly known as an ONO stack. In one embodiment, the optional dielectric liner 56 can include a silicon oxide layer that is substantially free of carbon or a silicon oxynitride layer that is substantially free of carbon. The thickness of the optional dielectric liner 56 can be in a range from 2 nm to 20 nm, although lesser and greater thicknesses can also be employed. The stack of the blocking dielectric layer 52, the memory material layer 54, and the optional dielectric liner 56 constitutes a memory film 50 that stores memory bits.

The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity 49′ is formed in the volume of each memory opening 49 that is not filled with the deposited material layers (52, 54, 56, 60L).

Referring to FIG. 4C, in case the cavity 49′ in each memory opening is not completely filled by the semiconductor channel material layer 60L, a dielectric core layer can be deposited in the cavity 49′ to fill any remaining portion of the cavity 49′ within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the topmost insulating layer 32T can be removed, for example, by a recess etch. The recess etch continues until top surfaces of the remaining portions of the dielectric core layer are recessed to a height between the top surface of the topmost insulating layer 32T and the bottom surface of the topmost insulating layer 32T. Each remaining portion of the dielectric core layer constitutes a dielectric core 62.

Referring to FIG. 4D, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the optional dielectric liner 56, the memory material layer 54, and the blocking dielectric layer 52 that overlie the horizontal plane including the top surface of the topmost insulating layer 32T can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. A optional dielectric liner 56 is surrounded by a memory material layer 54, and laterally surrounds a vertical semiconductor channel 60. Each adjoining set of a blocking dielectric layer 52, a memory material layer 54, and an optional dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a optional dielectric liner 56, a plurality of memory elements comprises portions of the memory material layer 54, and an optional blocking dielectric layer 52. Each combination of a memory stack structure 55, a dielectric core 62, and a drain region 63 within a memory opening 49 constitutes a memory opening fill structure 58.

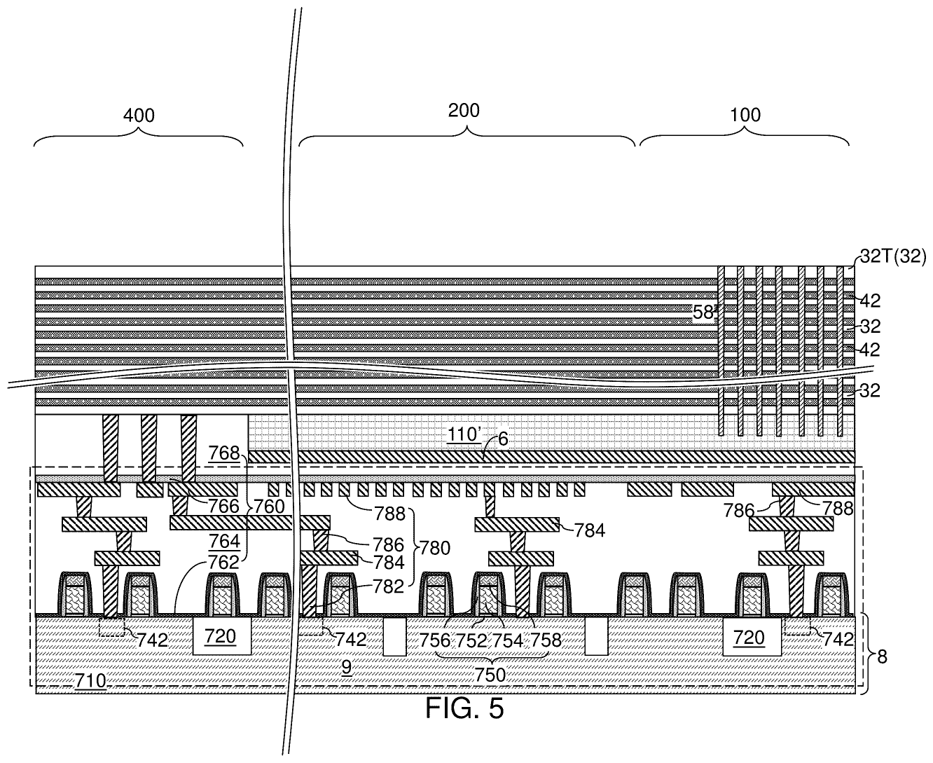

Referring to FIG. 5, the first exemplary structure is shown after formation of memory opening fill structures 58 in the memory openings 49. Each memory opening 49 is filled with a respective memory opening fill structure 58. Each memory opening fill structure 58 comprises a respective vertical semiconductor channel 60 and a respective vertical stack of memory elements (e.g., memory cells).

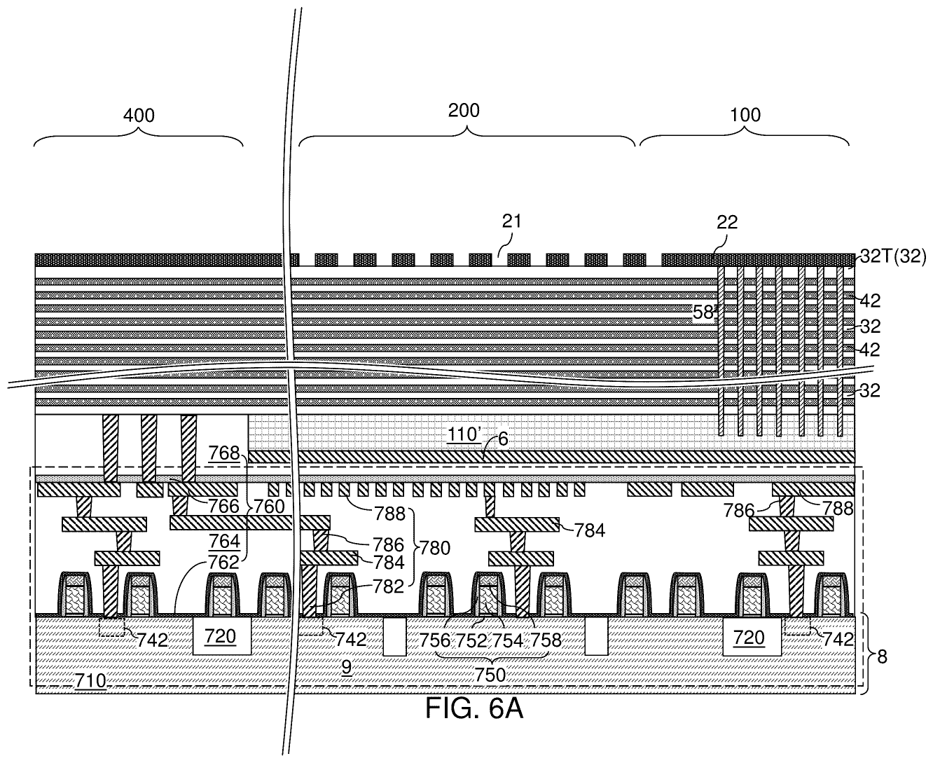

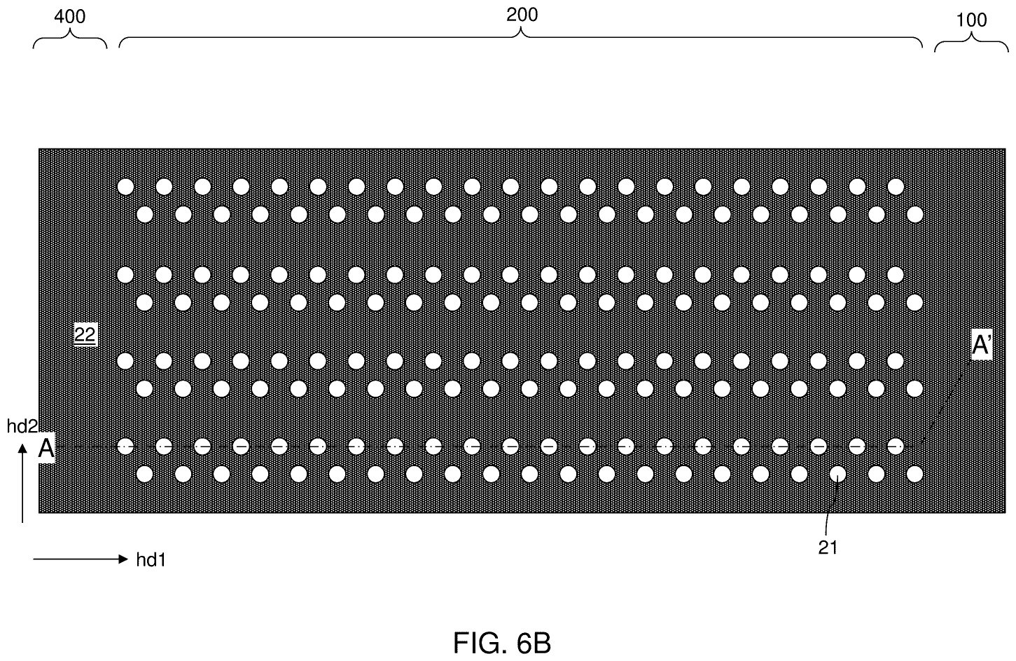

Referring to FIGS. 6A and 6B, a patterned hard mask layer 22 can be formed over the alternating stack (32, 42) of insulating layers 32 and sacrificial material layers 42. The patterned hard mask layer 22 can be formed by depositing a blanket etch mask layer (i.e., an unpatterned hard mask layer) over the alternating stack (32, 42), by applying a photoresist layer (not shown) over the blanket etch mask layer and lithographically patterning the photoresist layer, and by transferring a pattern in the patterned photoresist layer though the blanket etch mask layer by performing an anisotropic etch process that etches unmasked portions of the blanket etch mask layer that are not covered by the patterned photoresist layer. The patterned photoresist layer can be subsequently removed, for example, by ashing.

The patterned hard mask layer 22 may comprise arrays of mask openings 21. Each array of mask openings 21 comprises a plurality of openings that are located between a respective strip region that laterally extends along the first horizontal direction hd1. Generally, the arrays of mask openings 21 may be laterally spaced apart along the second horizontal direction hd2. Each array of mask openings 21 may be laterally offset along the first horizontal direction hd1 from a respective array of memory opening fill structures 58 located in the memory array region 100. The patterned hard mask layer 22 may be composed of a hard mask material. A hard mask material refers to a non-ashable mask material, i.e., a material that cannot be removed employing normal ashing processes. In contrast, a photoresist material is an ashable material, and thus, is not a hard mask material. In one embodiment, the patterned hard mask layer 22 may comprise a metallic material (such as TiN, TaN, WN, Ti, Ta, W, Ru, etc.) and/or an inorganic dielectric material (such as silicon nitride, silicon carbide, silicon carbide nitride, or at least one dielectric metal oxide material). The thickness of the patterned hard mask layer 22 may be in a range from 100 nm to 1,000 nm, although lesser and greater thicknesses may also be employed.

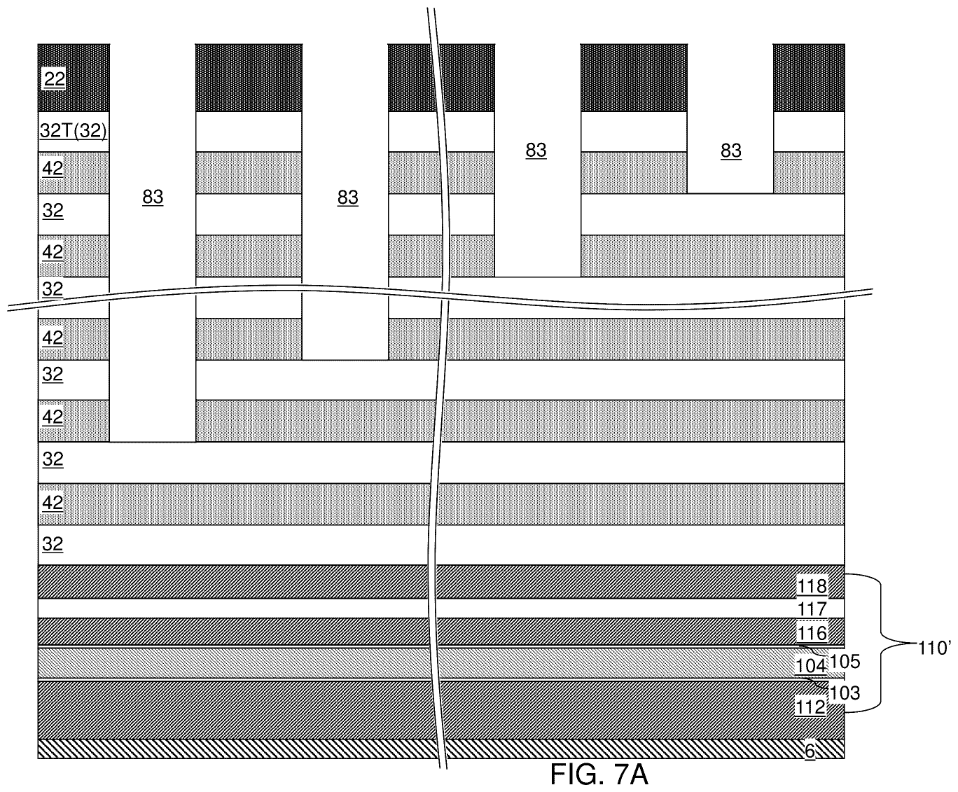

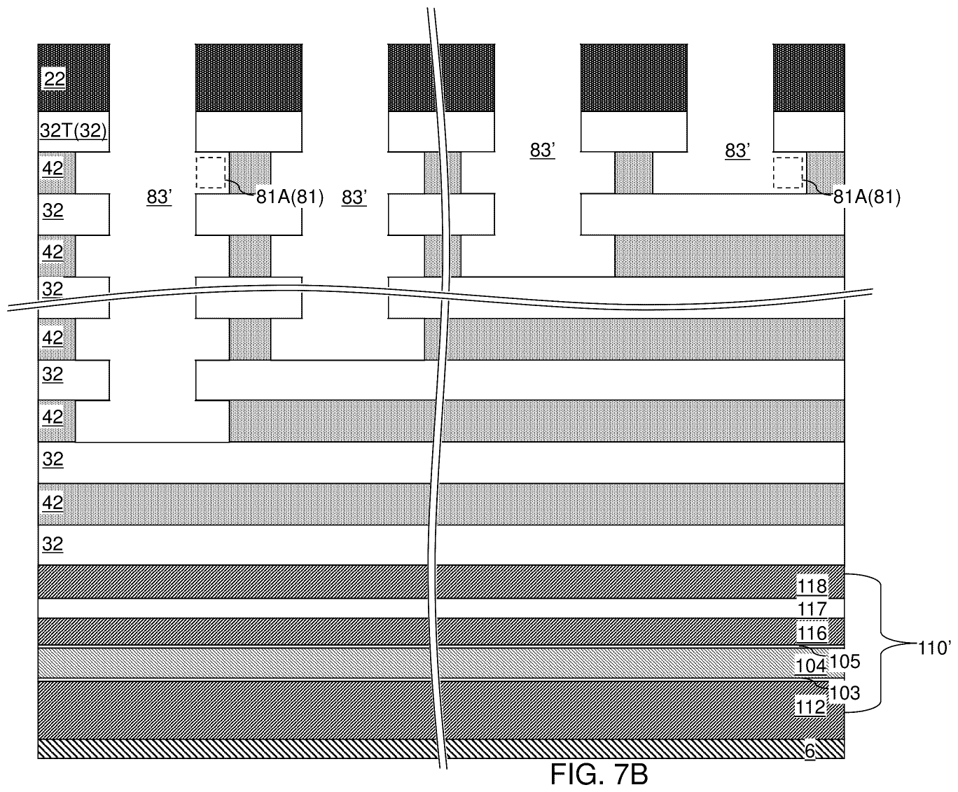

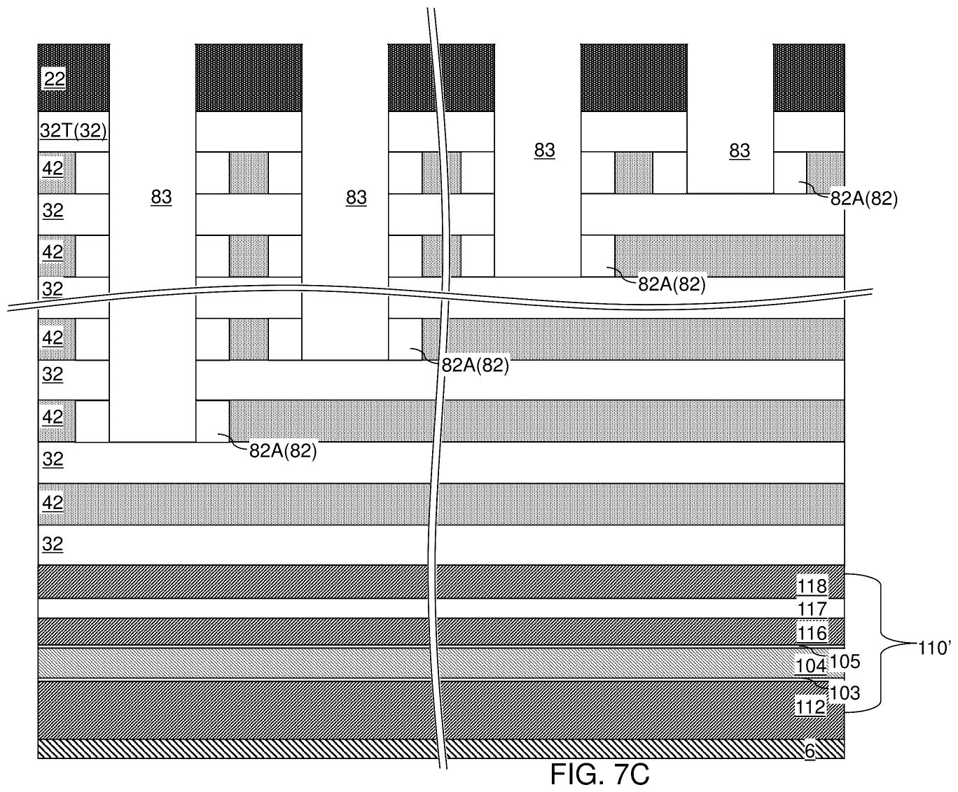

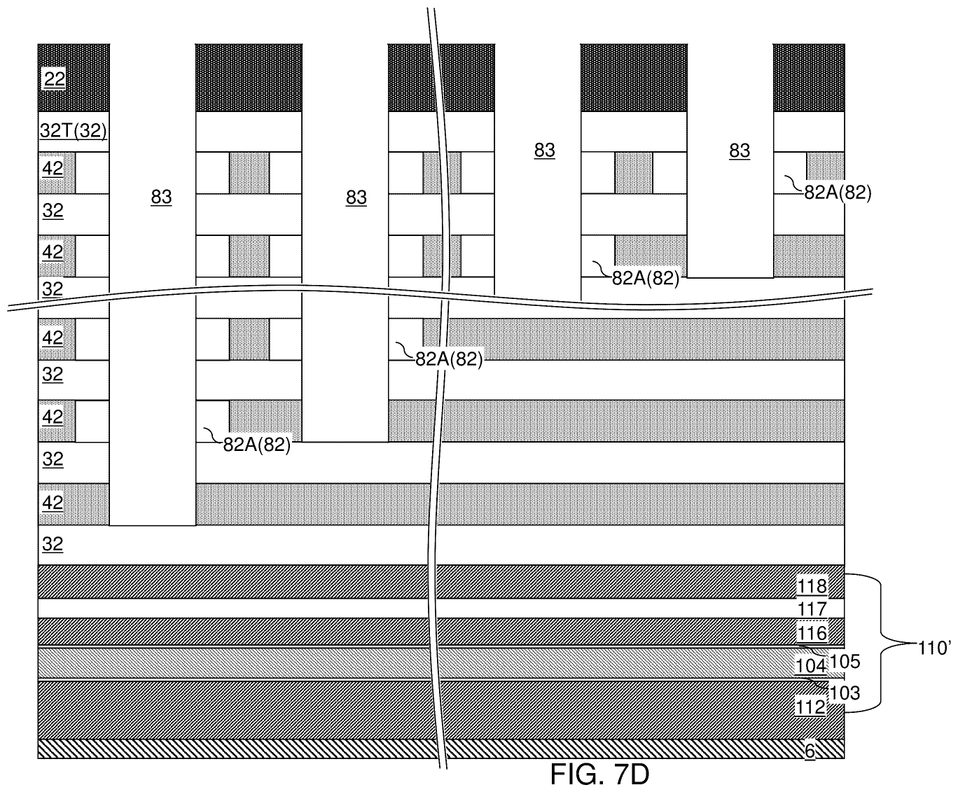

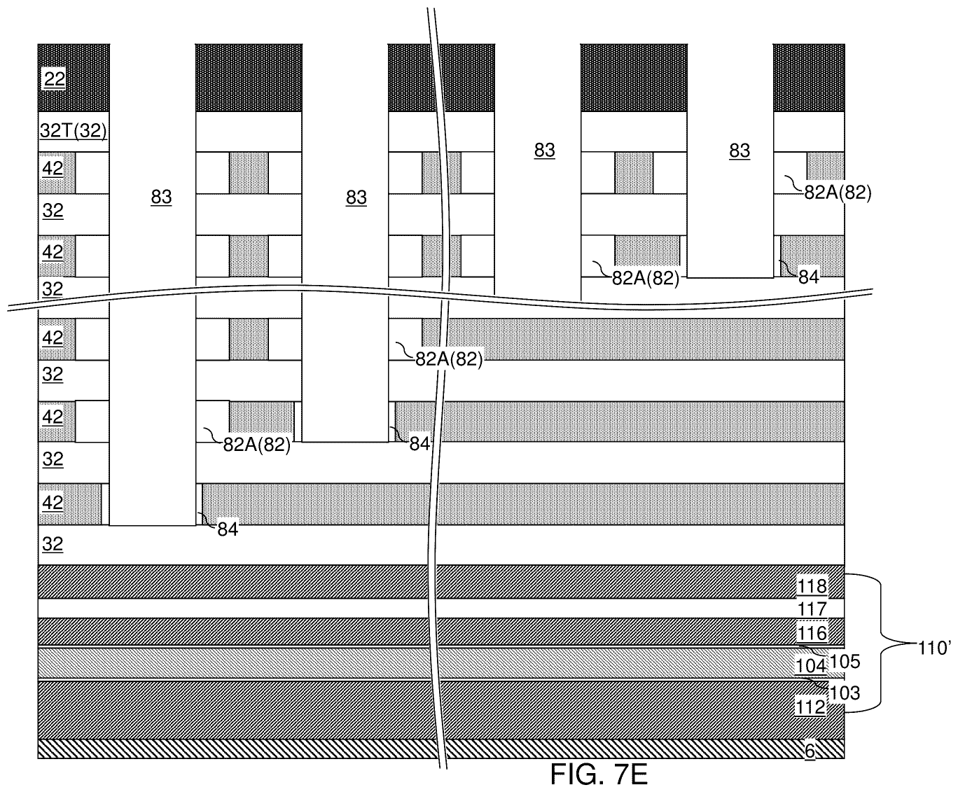

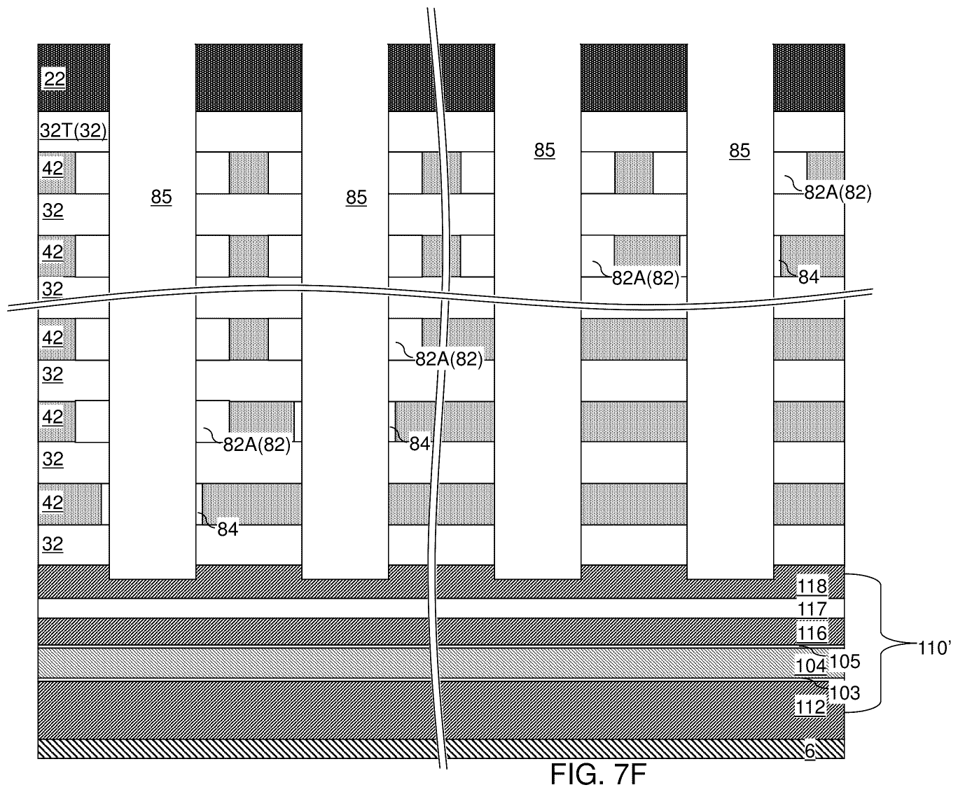

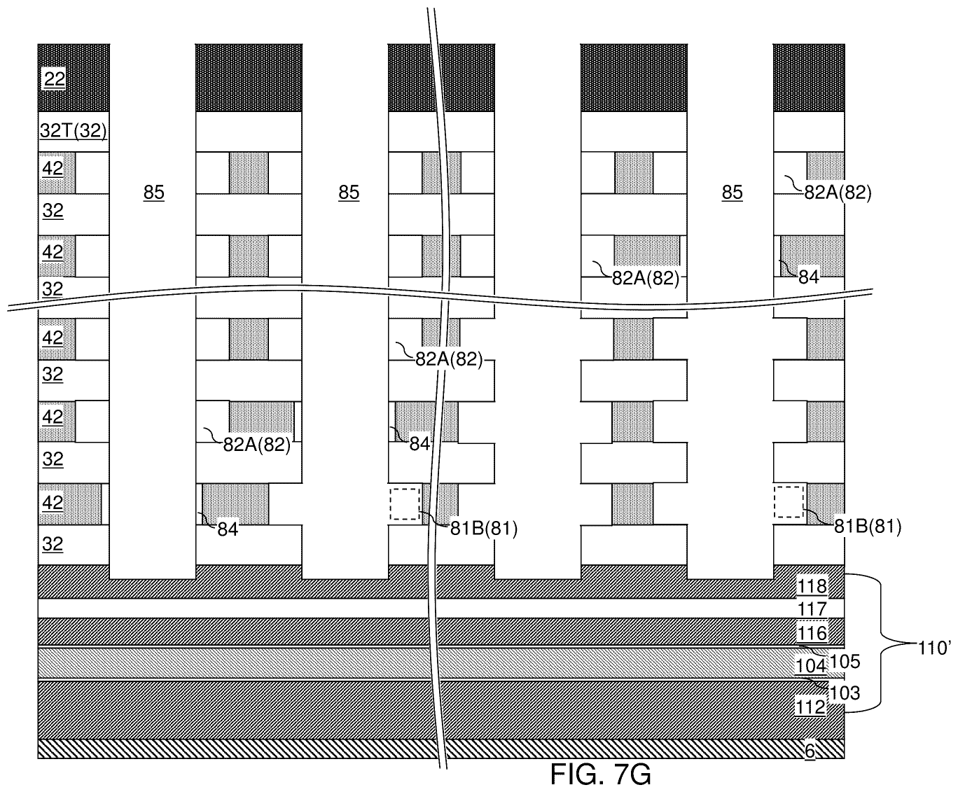

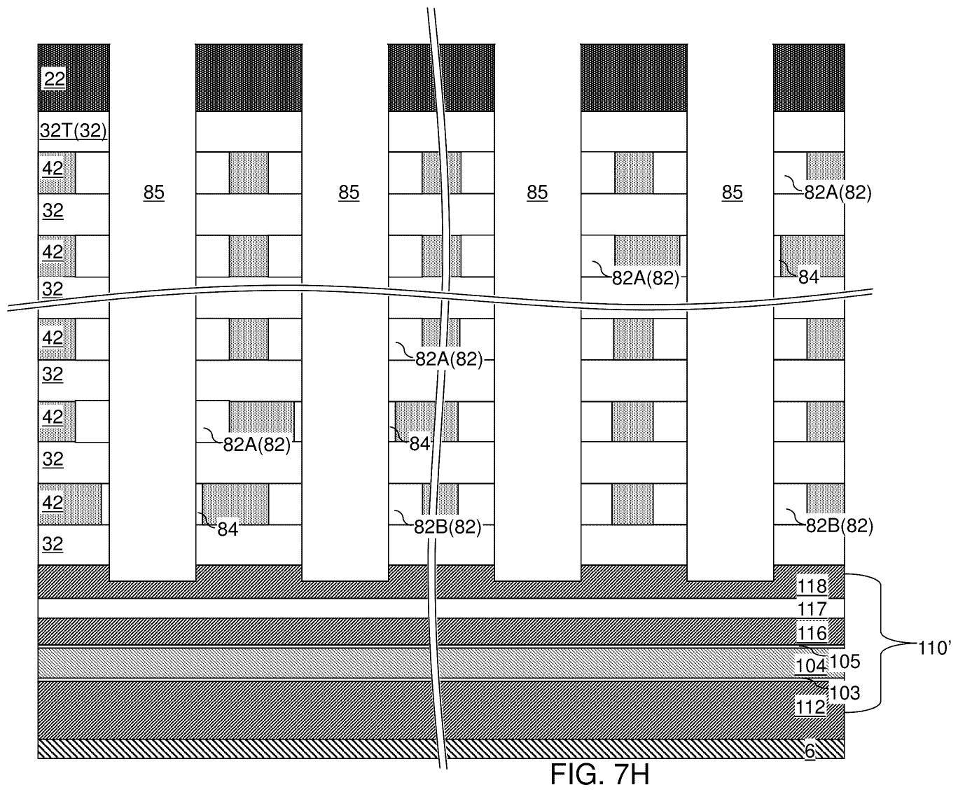

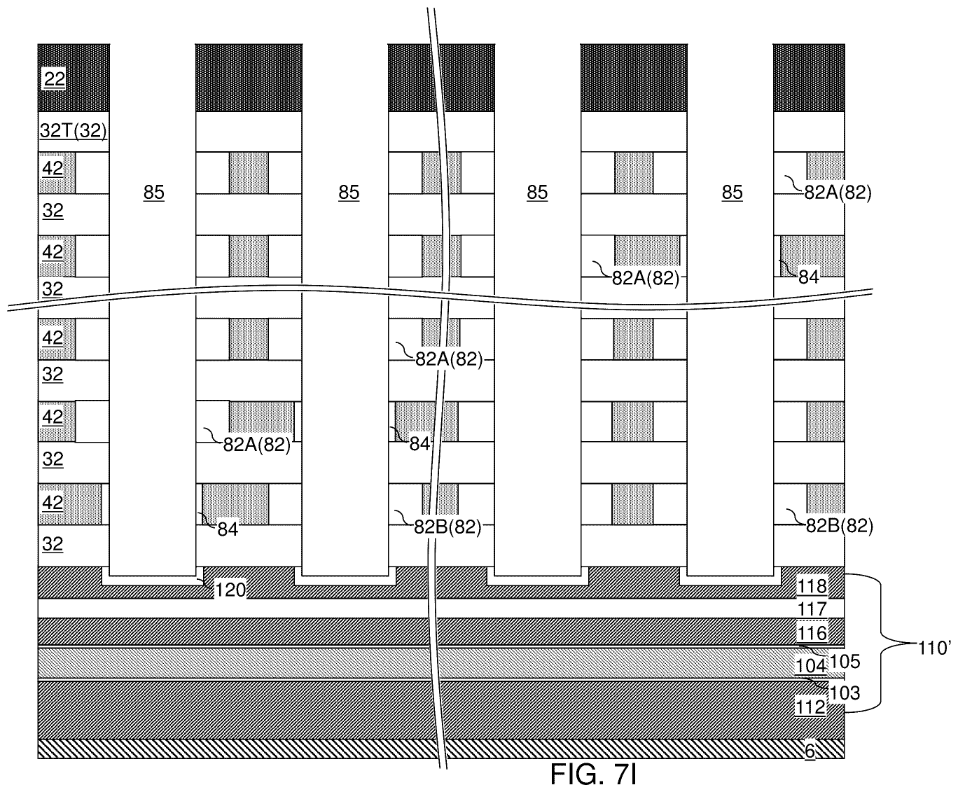

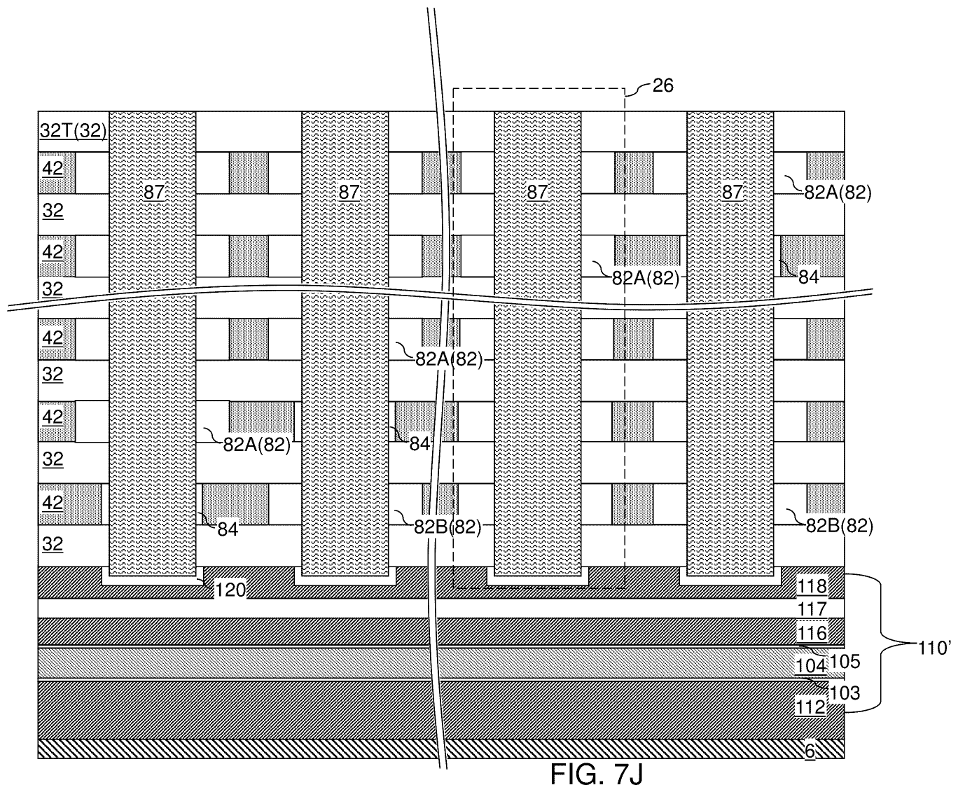

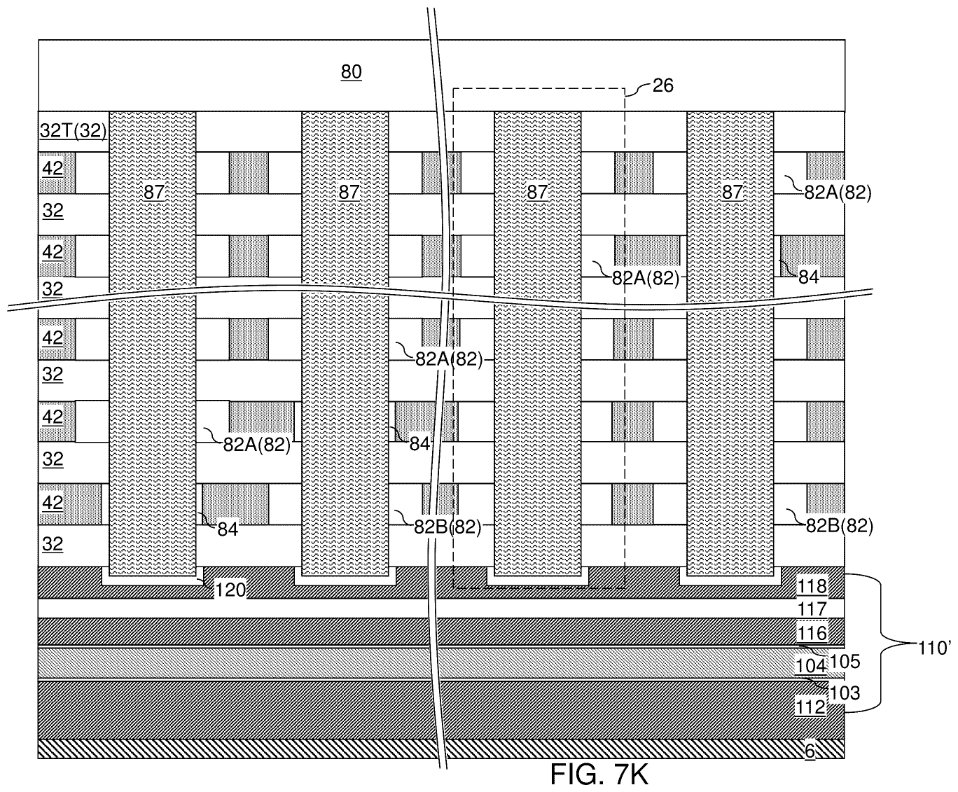

FIGS. 7A-7K are sequential vertical cross-sectional view of a contact region during formation of in-process layer contact assemblies 26 according to the first embodiment of the present disclosure.

Referring to FIG. 7A, a combination of an etch mask formation process and an anisotropic etch process may be repeated N times with variations in the patterns of openings in the etch masks and with changes in the duration of the anisotropic etch processes. The integer N may be in integer from 2 to 10, such as from 3 to 8.

For each i-th iteration of the combination of an etch mask formation process and an anisotropic etch process for which the integer i runs from 1 to N, an i-th masking layer, such as an i-th photoresist, can be applied over the patterned hard mask layer 22, and can be lithographically patterned to form openings therethrough. The areas of the pattern of the openings in the i-th masking layer includes areas of an i-th subset of the mask openings 21 in the patterned hard mask layer 22. In one embodiment, the i-th subset of the mask openings 21 may comprise about one half of all i-th subset of the mask openings 21.

An i-th anisotropic etch process can be performed to transfer the pattern of the openings in the i-th masking layer through a respective set of F(i) insulating layers 32 and F(i) sacrificial material layers 42 within each opening in the i-th masking layer. In one embodiment, each function F(i) may have a different positive integer value for each integer value i. In one embodiment, the value of each function F(i) may be positive integers that are integer powers of 2. In an illustrative example, F(i) may be 2⁽ⁱ⁻¹⁾. In another example, F(i) may be 2^{(N-i)}. In yet another example, the set of all values for F(i), 0<i<N+1, may include all integer powers of 2 between 1 and 2^{N-1} in any order. In still another example, the set of all values of F(i) may include any set of non-overlapping positive integers less than 2^{N-1}.

In one embodiment, the insulating layers 32 can include silicon oxide and the sacrificial material layers 42 can include a sacrificial material such as silicon nitride. In this case, an anisotropic etch process that etches F(i) pairs of insulating layers 32 and sacrificial material layers 42 can include F(i) iterations of a first anisotropic etch step that etches the sacrificial material of the sacrificial material layers 42 selective to silicon oxide, and a second anisotropic etch step that etches silicon oxide selective to the sacrificial material of the sacrificial material layers 42. The i-th subset of the in-process contact openings 83 can be vertically extended through a respective contiguous set of F(i) sacrificial material layers 42 and F(i) insulating layers 32. The i-th subset of the in-process contact openings 83 can be vertically extended through a respective contiguous set of F(i) sacrificial material layers 42 and F(i) insulating layers 32. The i-th masking layer can be subsequently removed, for example, by ashing and/or selective etching.

Generally, the masking patterns for the N masking layers (which may be N patterned photoresist layers) and the set of values for F(i), 0<i<N+1, may be selected such that via openings, which are herein referred to as in-process contact openings 83, that are formed underneath the mask openings 21 in the patterned photoresist layer have different depths. In one embodiment, the masking patterns for the N masking layers (which may be N patterned photoresist layers) and the set of values for F(i), 0<i<N+1, may be selected such that each sacrificial material layer 42 other than the bottommost sacrificial material layer 42 is physically exposed to a respective in-process contact opening 83 within each array of in-process contact openings 83 that underlie a respective array of mask openings 21. Each array of in-process contact openings 83 may be formed between a respective pair of strip regions in the patterned hard mask layer 22 that are free of any mask opening 21 therein.

Generally, at least one alternating stack of insulating layers 32 and sacrificial material layers 42 can be formed over the substrate 8, and in-process contact openings 83 can be formed through the at least one alternating stack (32, 42). According to an aspect of the present disclosure, each of the in-process contact openings 83 vertically extends through a respective first subset of layers within the alternating stack (32, 42).

Referring to FIG. 7B, a first selective isotropic etch process can be performed to isotropically etch the material of the sacrificial material layers 42 selective to the material of the insulating layers 32. First annular cavities 81A can be formed at each level of physically exposed sacrificial material layers 42 around each in-process contact opening 83. The first annular cavities 81A are a first subset of annular cavities 81 that are formed around contact openings that are formed underneath the mask openings 21 in the hard mask layer 22. In an illustrative example, the insulating layers 32 may comprise silicon oxide, the sacrificial material layers 42 may comprise silicon nitride, and the first selective isotropic etch process may comprise a timed wet etch process employing phosphoric acid. The duration of the first selective isotropic etch process may be selected such that the lateral etch distance may be in a range from 5 nm to 100 nm, such as from 10 nm to 50 nm, although lesser and greater lateral etch distances may also be employed. The first annular cavities 81A are formed within annular volumes from which the material of the sacrificial material layers 42 are removed. Each contiguous combination of an in-process contact opening 83 and at least one first annular cavity 81A constitutes a finned opening 83′, which is also referred to as a finned cavity.

Referring to FIG. 7C, a dielectric fill material such as undoped silicate glass (i.e., silicon oxide), a doped silicate glass, or a dielectric metal oxide material can be conformally deposited in the first annular cavities 81A. An anisotropic etch process can be performed to remove portions of the dielectric fill material that are deposited outside the volume of the first annular cavities 81A. Each remaining portion of the dielectric fill material that fills a respective first annular cavity 81A is herein referred to as a first annular dielectric spacer 82A, or as an upper annular dielectric spacer 82A. The first annular dielectric spacers 82A are a first subset of annular dielectric spacers 82 that are formed around via openings underneath the mask openings 21 in the patterned hard mask layer 22. Generally, the first annular dielectric spacers 82A (i.e., the first subset of the annular dielectric spacers 82) can be formed by replacing proximal portions of the sacrificial material layers 42 with dielectric material portions around the in-process contact openings 83. In one embodiment, inner cylindrical sidewalls of the first annular dielectric spacers 82A may be vertically coincident with (i.e., located within a same vertical plane as) physically exposed sidewalls of the insulating layers 32 around each in-process contact opening 83.

Referring to FIG. 7D, an anisotropic etch process can be performed to vertically extend each in-process contact opening 83 through a respective underlying pair of an insulating layer 32 and a sacrificial material layer 42. The patterned hard mask layer 22 is employed as an etch mask during the anisotropic etch process. Each in-process contact opening 83 can be vertically extended downward through a respective underlying insulating layer 32 and a respective underlying spacer material layer (such as a respective underlying sacrificial material layer 42) within the at least one alternating stack (32, 42) that are located underneath the bottom surface of the respective in-process contact opening 83. A cylindrical sidewall of the underlying sacrificial material layer 42 can be physically exposed to each vertically extended in-process contact opening 83.

Referring to FIG. 7E, annular sacrificial spacers 84 can be formed on remaining portions of a respective underlying spacer material layer 42 after vertically extending the in-process contact openings 83. In other words, the annular sacrificial spacers 84 can be formed on each portion of the sacrificial material layers 42 that are physically exposed to the in-process contact openings. In one embodiment, each of the annular sacrificial spacers 84 may be self-aligned to the physically exposed sidewalls of the sacrificial material layers 42.

In an illustrative example, the sacrificial material layers 42 may be composed of a silicon nitride material, and the annular sacrificial spacers 84 may be formed by oxidation of physically exposed surface portions of the sacrificial material layers 42. The oxidation process may comprise a thermal oxidation process or a plasma oxidation process. In this case, the annular sacrificial spacers 84 may comprise silicon oxide and/or silicon oxynitride. In one embodiment, the annular sacrificial spacers 84 may be formed by oxidation of tubular surface portions of physically exposed spacer material layers, which may be embodied as the sacrificial material layers 42.

In an alternative example, the sacrificial material layers 42 may be isotropically recessed relative to the insulating layers 32 to form annular recesses which have a smaller lateral width (i.e., thickness) than that of the finned annular cavities 81A. A dielectric fill material may be conformally deposited in the annular recesses, and an anisotropic etch process may be performed to remove portions of the dielectric fill material that are deposited outside the volumes of the annular recesses. Portions of the dielectric fill material that fill the annular recesses constitute the annular sacrificial spacers 84.

The lateral thickness of each annular sacrificial spacer 84 may be less than the lateral thickness of each first annular dielectric spacer 82A. As used herein, a lateral thickness of an annular element refers to a lateral distance between an inner sidewall and an outer sidewall. In one embodiment, the lateral thickness of each annular sacrificial spacer 84 may be less than the lateral thickness of each first annular dielectric spacer 82A by at least 30%, such as 50% to 300%. In one embodiment, the lateral thickness of each annular sacrificial spacer 84 may be in range from 1 nm to 20 nm, such as from 2 nm to 10 nm, although lesser and greater lateral thicknesses may also be employed.

Referring to FIG. 7F, the in-process contact openings 83 may be vertically extended further downward after formation of the annular sacrificial spacers 84 by performing an additional anisotropic etch process. The etch chemistry of the additional anisotropic etch process may be selected such that the additional anisotropic etch process etches through the insulating layers 32 and the sacrificial material layers 42 underneath the in-process contact openings 83. The additional anisotropic etch process may have an etch chemistry that is selective to a semiconductor material in the in-process source-level material layers 110′, such as the heavily doped semiconductor material of the optional source-select-level conductive layer 118 or the semiconductor material of the upper source-level semiconductor layer 116 in case the optional source-select-level conductive layer 118 is not employed. The anisotropic etch process vertically extends the in-process contact openings 83 through each layer in the alternating stack (32, 42), and each of the in-process contact openings 83 reaches a maximum height. Each of the in-process contact openings 83 becomes a contact opening 85 after the additional anisotropic etch process. In one embodiment, a top surface of a semiconductor material layer (such as the optional source-select-level conductive layer 118 or the upper source-level semiconductor layer 116) of the in-process source-level material layers 110′ may be physically exposed upon formation of the contact openings 85 after the additional anisotropic etch process.

Referring to FIG. 7G, a second selective isotropic etch process can be performed to isotropically etch the material of the sacrificial material layers 42 selective to the material of the insulating layers 32. Second annular cavities 81B can be formed at each level of physically exposed sacrificial material layers 42 around each contact opening 85. The second annular cavities 81B are a second subset of annular cavities 81 that are formed around contact openings 85. In an illustrative example, the insulating layers 32 may comprise silicon oxide, the sacrificial material layers 42 may comprise silicon nitride, and the second selective isotropic etch process may comprise a timed wet etch process employing phosphoric acid. The duration of the second selective isotropic etch process may be selected such that the lateral etch distance may be in a range from 5 nm to 100 nm, such as from 10 nm to 50 nm, although lesser and greater lateral etch distances may also be employed. The second annular cavities 81B are formed within annular volumes from which the material of the sacrificial material layers 42 are removed. Each contiguous combination of a contact opening 85 and at least one second annular cavity 81B constitutes a finned opening, which is also referred to as a finned cavity.

Referring to FIG. 7H, a dielectric fill material such as undoped silicate glass, a doped silicate glass, or a dielectric metal oxide material can be conformally deposited in the second annular cavities 81B. An anisotropic etch process can be performed to remove portions of the dielectric fill material that are deposited outside the volume of the second annular cavities 81B. Each remaining portion of the dielectric fill material that fills a respective second annular cavity 81B is herein referred to as a second annular dielectric spacer 82B, or a lower annular dielectric spacer 82B. The second annular dielectric spacers 82B are a second subset of annular dielectric spacers 82 that are formed around contact openings 85. Generally, the second annular dielectric spacers 82B (i.e., the second subset of the annular dielectric spacers 82) can be formed by replacing proximal portions of the sacrificial material layers 42 with dielectric material portions around the contact openings 85 after formation of the annular sacrificial spacers 84. In one embodiment, inner cylindrical sidewalls of the second annular dielectric spacers 82B may be vertically coincident with (i.e., located within a same vertical plane as) physically exposed sidewalls of the insulating layers 32 around each contact opening 85. In one embodiment, the second annular dielectric spacers 82B may comprise the same material as the first annular dielectric spacers 82A. In one embodiment, the annular dielectric spacers 82 may comprise a dielectric material such as undoped silicate glass (e.g., silicon oxide), a doped silicate glass, or a dielectric metal oxide material.

Generally, a combination of a contact opening 85 and a vertical stack of annular dielectric spacers 82 and an annular sacrificial spacer 84 can be formed through at least one alternating stack (32, 42) of insulating layers 32 and spacer material layers underneath each mask opening 21 in the patterned hard mask layer 22. In one embodiment, plural annular dielectric spacers 82 and one annular sacrificial spacer 84 may be exposed in each contact opening 85. For a subset of the combinations of a respective contact opening 85 and a respective vertical stack of annular dielectric spacers 82 and a respective annular sacrificial spacer 84, the vertical stack of annular dielectric spacers 82 may comprise at least one upper annular dielectric spacer 82A overlying the annular sacrificial spacer 84, and at least one lower annular dielectric spacer 82B underlying the annular sacrificial spacer 84. One of the spacer material layers (such as the sacrificial material layer 42) may be laterally spaced from the contact opening 85 by the annular sacrificial spacer 84.

The lateral thickness of each annular sacrificial spacer 84 may be less than the lateral thickness of each annular dielectric spacers 82 (i.e., 82A and 82B). In one embodiment, the lateral thickness of each annular sacrificial spacer 84 may be less than the lateral thickness of each annular dielectric spacers 82 (e.g., first and second annular dielectric spacers (82A, 82B)) by at least 30%, such as 50% to 300%.

Referring to FIG. 7I, an oxidation process may be performed to convert physically exposed surface portions of the topmost semiconductor material layer (such as the optional source-select-level conductive layer 118 or the upper source-level material layer 116) into semiconductor oxide plates 120. The oxidation process may comprise a thermal oxidation process or a plasma oxidation process. The thickness of the semiconductor oxide plates 120 may be in a range from 4 nm to 40 nm, such as from 6 nm to 20 nm, although lesser and greater thicknesses may also be employed.

Referring to FIG. 7J, a sacrificial fill material can be deposited into the contact openings 85. The sacrificial fill material comprises a material that can be subsequently removed selective to materials of the annular dielectric spacers 82, the annular sacrificial spacers 84, the insulating layers 32, and the semiconductor oxide plates 120. For example, the sacrificial fill material may comprise a semiconductor material (such as amorphous silicon, polysilicon, or a silicon-germanium alloy), a carbon-based material (such as amorphous carbon or diamond-like carbon), organosilicate glass, a polymer material, etc. Excess portions of the sacrificial fill material may be removed from above the horizontal plane including the top surface of the topmost insulating layer 32T. The patterned hard mask layer 22 may be removed selective to the materials of the topmost insulating layer 32T and the sacrificial fill material, for example, employing an etch process such as a wet etch process. Each remaining portion of the sacrificial fill material that fills a respective contact opening 85 constitutes a sacrificial contact opening fill structure 87. Each of the sacrificial contact opening fill structure 87 may have a respective cylindrical shape. In one embodiment, top surfaces of the sacrificial contact opening fill structures 87 may be formed within the horizontal plane including the top surface of the topmost insulating layer 32T. Each contiguous combination of a sacrificial contact opening fill structure 87, a vertical stack of annular dielectric spacers 82, and an annular sacrificial spacer 84 is herein referred to as an in-process layer contact assembly 26. Arrays of in-process layer contact assemblies 26 are formed through the at least one alternating stack (32, 42) of insulating layers 32 and spacer material layers (such as sacrificial material layers 42).

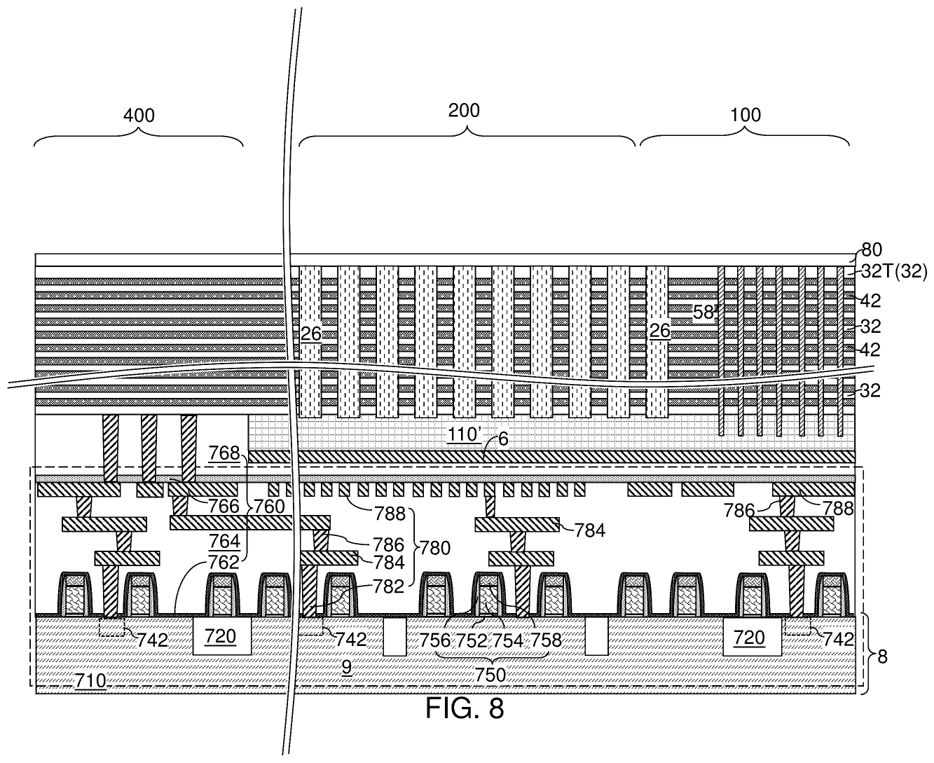

Referring to FIGS. 7K and 8, a contact-level dielectric layer 80 may be formed above the alternating stack (32, 42) and the in-process layer contact assemblies 26 by conformal or non-conformal deposition of a dielectric material. The contact-level dielectric layer 80 comprises a dielectric material such as undoped silicate glass or a doped silicate glass. The thickness of the contact-level dielectric layer 80 may be in a range from 50 nm to 600 nm, such as from 100 nm to 300 nm, although lesser and greater thicknesses may also be employed.

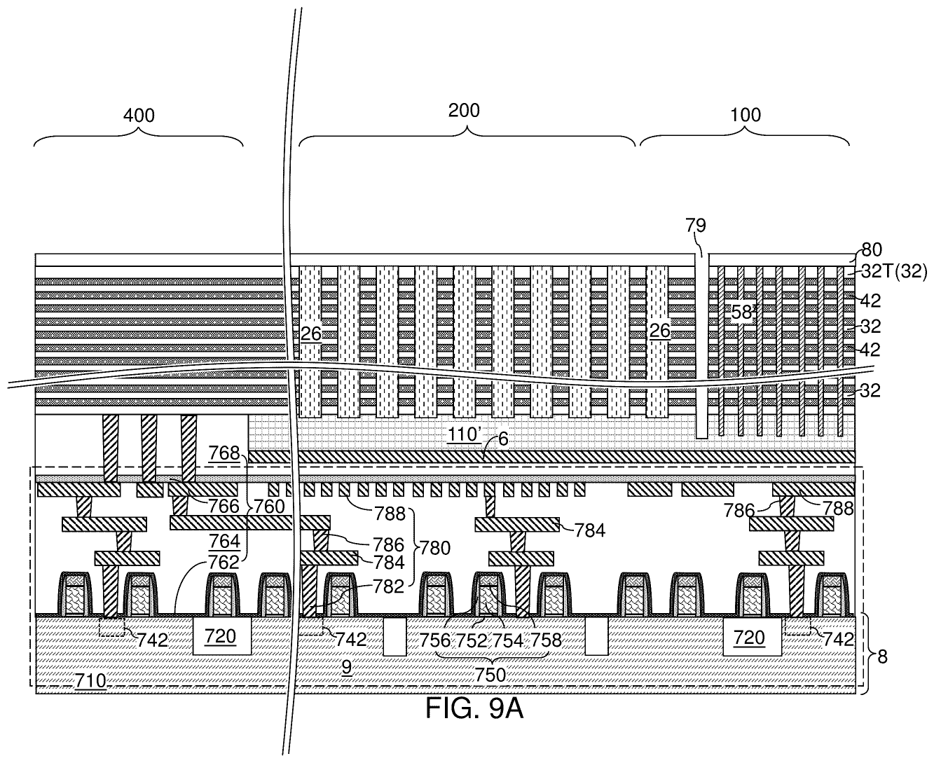

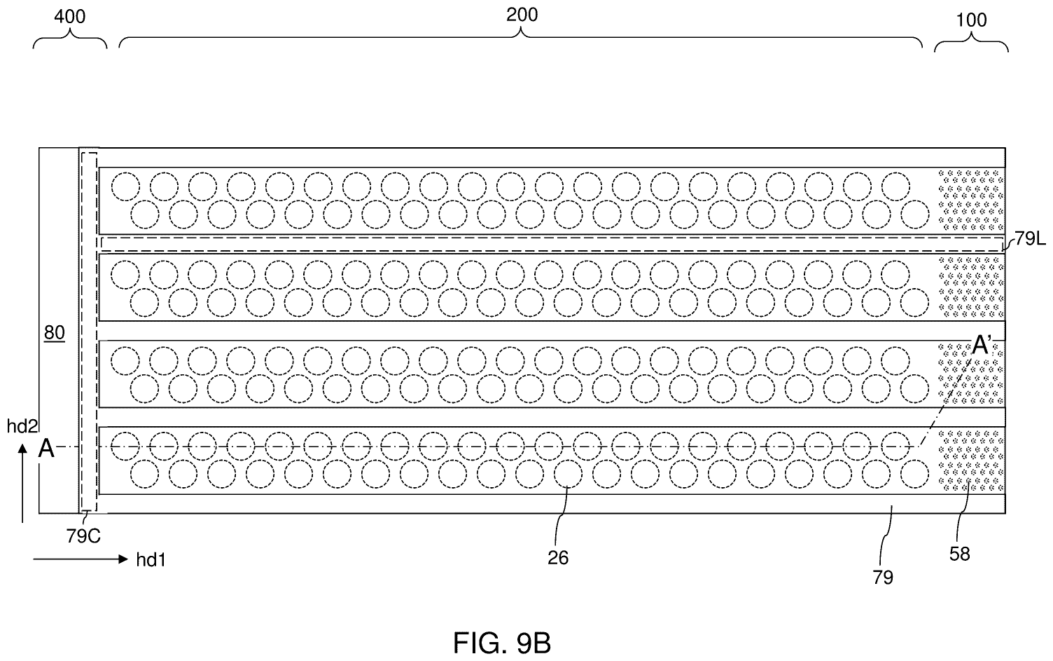

Referring to FIGS. 9A and 9B, a photoresist layer (not shown) can be applied over the contact-level dielectric layer 80, and is lithographically patterned to form first elongated openings in areas between clusters of memory opening fill structures 58 and to form a second elongated opening that is connected to end portions of the first elongated openings. The pattern in the photoresist layer can be transferred through the contact-level dielectric layer 80 and the alternating stack (32, 42) employing an anisotropic etch to form backside trenches 79. The backside trenches 79 vertically extend from the top surface of the contact-level dielectric layer 80 to the top surface of the topmost semiconductor material layer that underlies the alternating stack (32, 42). The backside trenches 79 comprise lengthwise backside trenches 79L that laterally extend along the first horizontal direction hd1 between neighboring arrays of memory opening fill structures 58 and between neighboring arrays of in-process layer contact assemblies 26. The backside trenches 79 may further comprise a connection backside trench 79C that is connected to end portions of the lengthwise backside trenches 79L and laterally extends along the second horizontal direction hd2. In one embodiment, the lengthwise backside trenches 79L may laterally extend through the memory array region 100 and the contact region 200. The connection backside trench 79C may be formed in proximity to a boundary between the contact region 200 and the connection region 400.

In one embodiment, the lengthwise backside trenches 79L can laterally extend along the first horizontal direction hd1 and can be laterally spaced apart from each other along the second horizontal direction hd2 that is perpendicular to the first horizontal direction hd1. The memory opening fill structures 58 can be arranged in rows that extend along the first horizontal direction hd1. Multiple rows of memory opening fill structures 58 can be located between each neighboring pair of lengthwise backside trenches 79L. The photoresist layer can be removed, for example, by ashing.

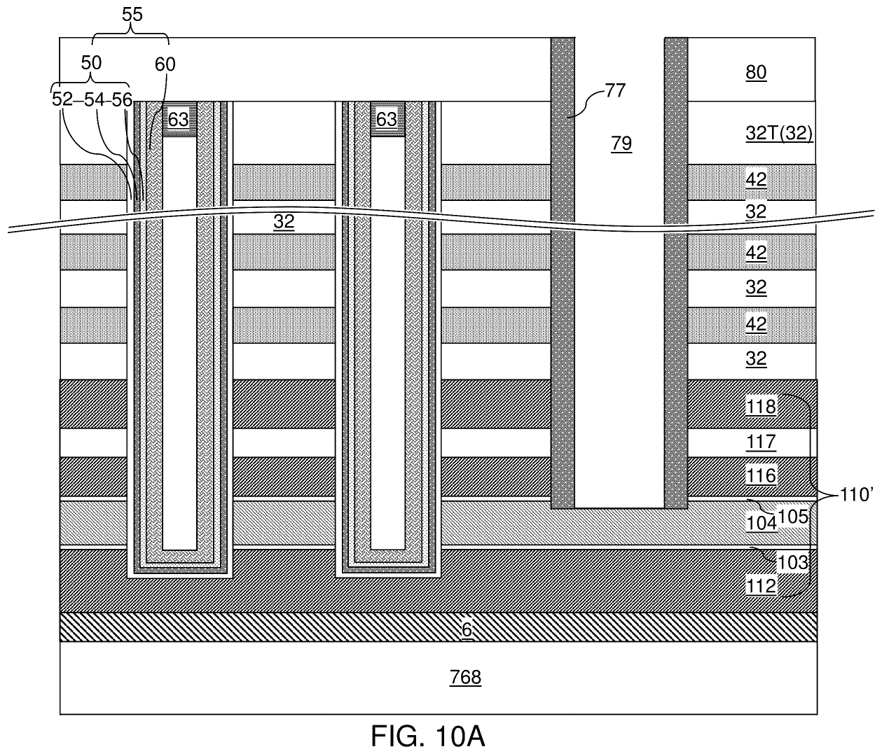

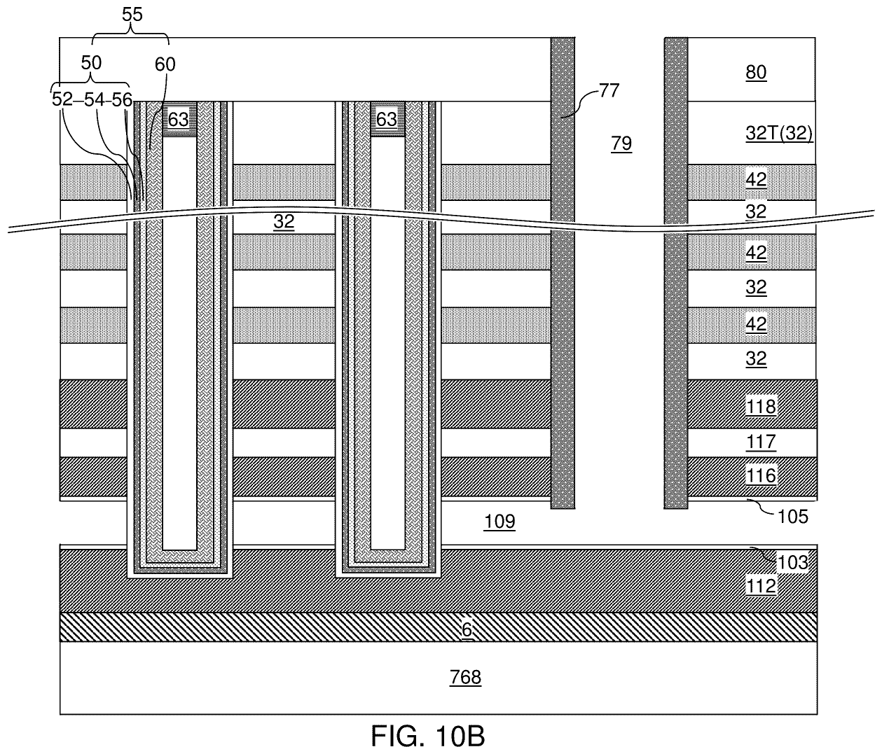

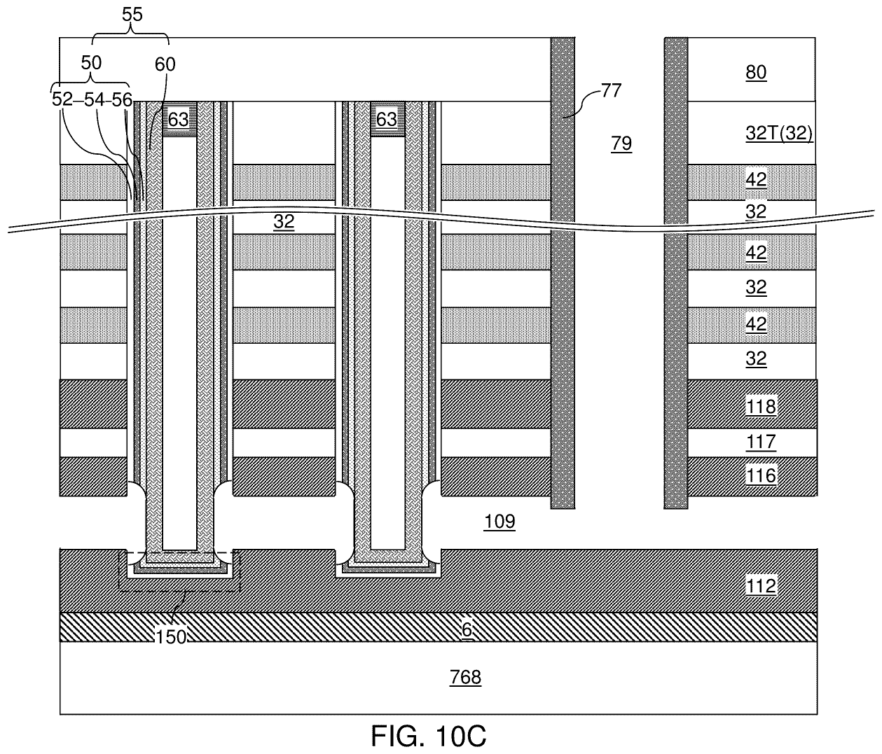

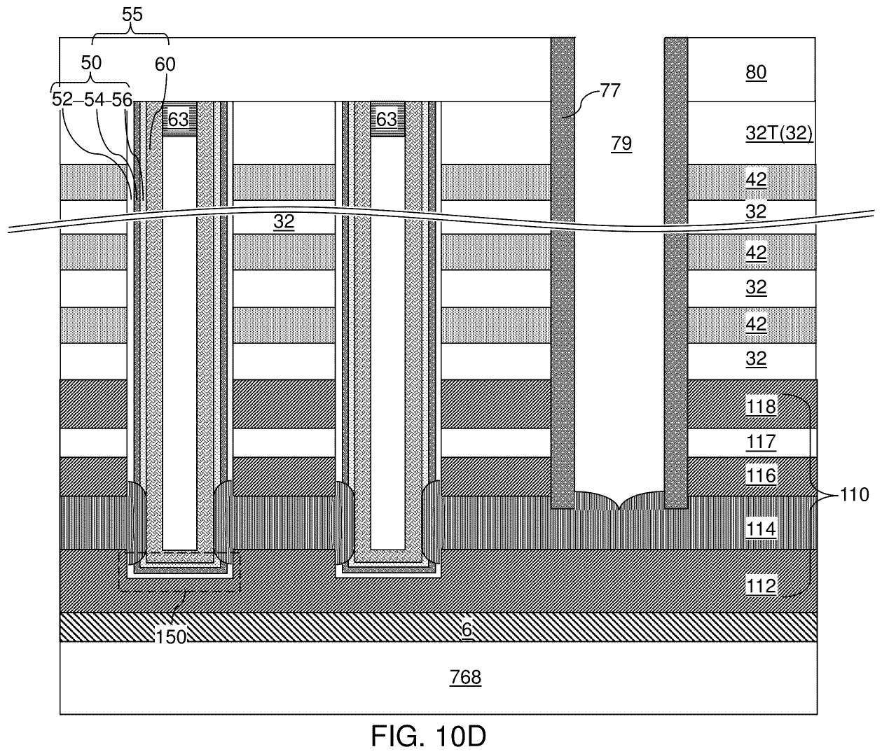

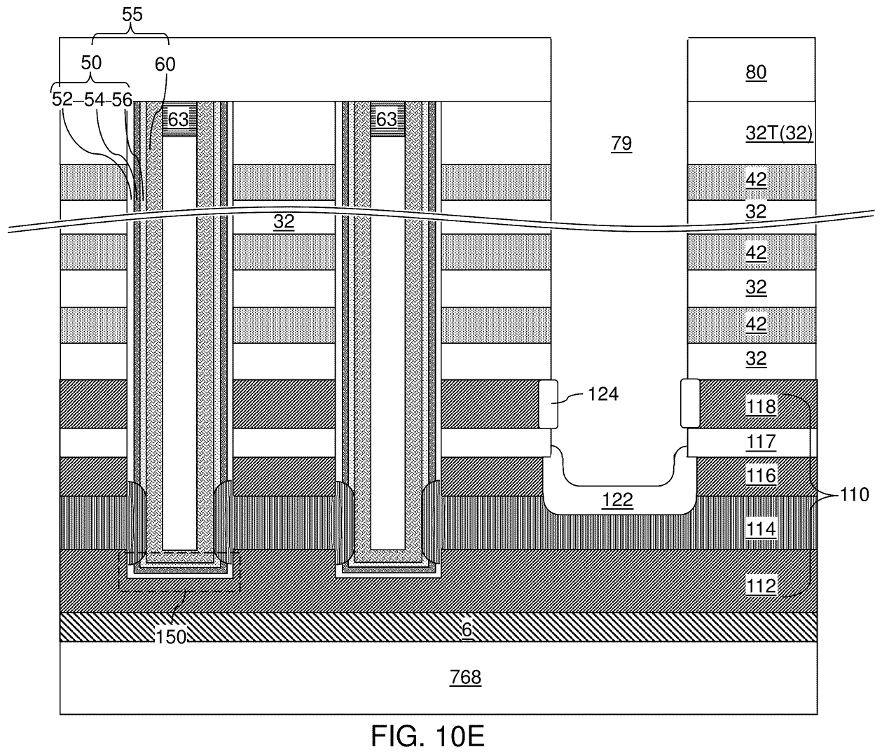

FIGS. 10A-10E are sequential vertical cross-sectional views of a region of the first exemplary structure during replacement of a source-level sacrificial layer 104 with a source contact layer 114 according to the first embodiment of the present disclosure.

Referring to FIG. 10A, a backside trench spacer 77 can be formed on sidewalls of each backside trench 79. For example, a conformal spacer material layer can be deposited in the backside trenches 79 and over the contact-level dielectric layer 80, and can be anisotropically etched to form the backside trench spacers 77. The backside trench spacers 77 include a material that is different from the material of the source-level sacrificial layer 104. For example, the backside trench spacers 77 can include silicon oxide, a dielectric metal oxide, or silicon nitride.

Referring to FIG. 10B, an etchant that etches the material of the source-level sacrificial layer 104 selective to the materials of the backside trench spacer 77, the contact-level dielectric layer 80, the upper dielectric liner layer 105, and the lower dielectric liner layer 103 can be introduced into the backside trenches 79 in an isotropic etch process. For example, if the source-level sacrificial layer 104 includes undoped amorphous silicon or an undoped amorphous silicon-germanium alloy, the backside trench spacers 77 include silicon nitride, and the upper and lower dielectric liner layers (105, 103) include silicon oxide, a wet etch process employing hot trimethyl-2 hydroxyethyl ammonium hydroxide (“hot TMY”) or tetramethyl ammonium hydroxide (TMAH) can be employed to remove the source-level sacrificial layer 104 selective to the backside trench spacers 77 and the upper and lower dielectric liner layers (105, 103). Alternatively, if the source-level sacrificial material layer 104 includes silicon nitride, the backside trench spacers 77 include silicon oxide or a dielectric metal oxide, and the upper and lower dielectric liner layers (105, 103) include silicon oxide, a wet etch process employing hot phosphoric acid can be employed to remove the source-level sacrificial layer 104 selective to the backside trench spacers 77 and the upper and lower dielectric liner layers (105, 103). A source cavity 109 is formed in the volume from which the source-level sacrificial layer 104 is removed.

Referring to FIG. 10C, a sequence of isotropic etchants, such as wet etchants, can be applied through the backside trenches 79 and the source cavity 109 to the physically exposed portions of the memory films 50 to sequentially etch the various component layers of the memory films 50 from outside to inside, and to physically expose cylindrical side surfaces of the vertical semiconductor channels 60 at the level of the source cavity 109. The upper and lower dielectric liner layers (105, 103) can be collaterally etched during removal of the portions of the memory films 50 located at the level of the source cavity 109. The source cavity 109 can be expanded in volume by removal of the portions of the memory films 50 at the level of the source cavity 109 and the upper and lower dielectric liner layers (105, 103). A top surface of the lower source-level material layer 112 and a bottom surface of the upper source-level material layer 116 can be physically exposed to the source cavity 109. An outer sidewall of each vertical semiconductor channel 60 is physically exposed to the source cavity 109 after removing the physically exposed portions of the memory films 50. A dielectric material stack 150 is formed underneath each physically exposed cylindrical surface of the vertical semiconductor channels 60. Each dielectric material stack 150 is a remaining portion of the memory films 50, and includes the same dielectric material stack as the memory films 50.

Thus, the upper source-level material layer 116 can act as an etch stop during the selective etching of the memory film 50 through the source cavity 109 and can prevent vertical expansion of the source cavity 109. This prevents a short circuit between the source-select-level conductive layer 118 and a source contact layer that is subsequently formed in the source cavity 109 during a subsequent step.

Referring to FIG. 10D, a source contact layer 114 can be formed by a selective deposition process that deposits a doped semiconductor material having a doping of the second conductivity type, which is herein referred to as a third doped semiconductor material. The doped semiconductor material can include amorphous silicon, polysilicon, or a silicon-germanium alloy. The third doped semiconductor material of the source contact layer 114 can grow from physically exposed semiconductor surfaces around the source cavity 109. The average atomic concentration of dopants of the second conductivity type in the source contact layer 114 can be in a range from 5.0×10¹⁹/cm³ to 2.0×10²¹/cm³, although lesser and greater dopant concentrations can also be employed.

The in-process source-level material layers 110′ are replaced with source-level material layers 110. The source-level material layers 110 include a layer stack including, from bottom to top, the lower source-level material layer 112, the source contact layer 114, the upper source-level material layer 116, the source-level insulating layer 117, and the optional source-select-level conductive layer 118. The combination of the lower source-level material layer 112, the source contact layer 114, the upper source-level material layer 116 constitutes a source layer (112, 114, 116). Upon replacement of the source-level sacrificial layer 104 with a source contact layer 114, the in-process source-level material layers 110′ are converted into source-level material layers 110 including a source layer (112, 114, 116).

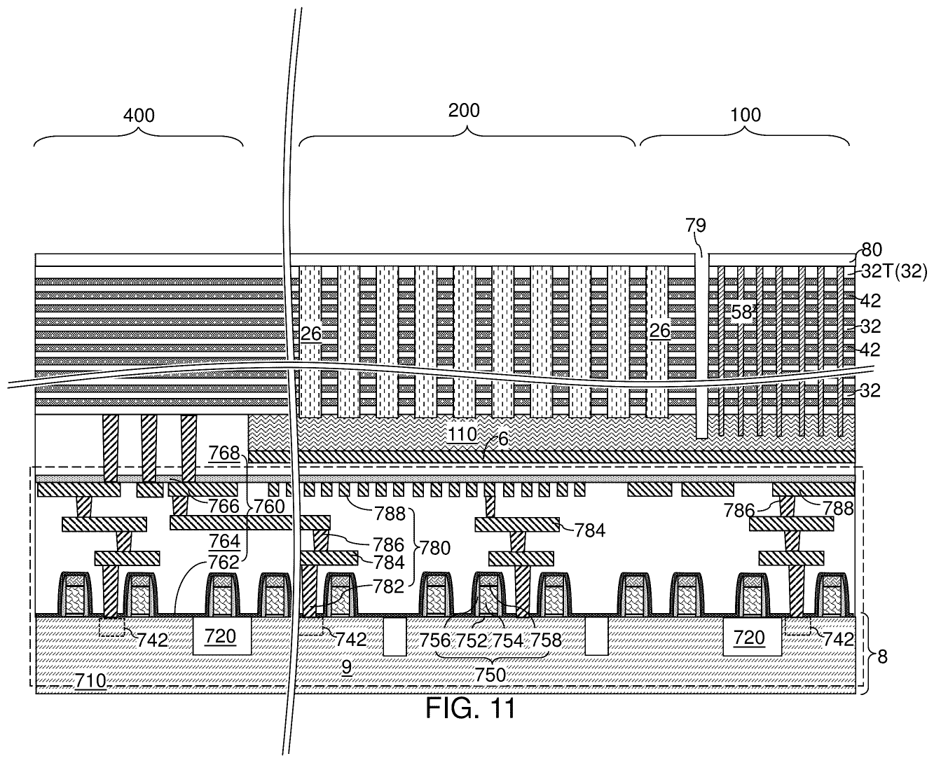

Referring to FIGS. 10E and 11, the backside trench spacers 77 can be removed selective to the semiconductor materials of the source contact layer 114. For example, if the backside trench spacers 77 include silicon nitride, a wet etch process employing hot phosphoric acid can be employed to remove the backside trench spacers 77. If the backside trench spacers 77 include silicon oxide, a wet etch process employing dilute hydrofluoric acid can be employed to remove the backside trench spacers 77. Sidewalls of the alternating stacks (32, 42), the upper source-level material layer 116, the source-level insulating layer 117, and the optional source-select-level conductive layer 118 can be physically exposed after removal of the backside trench spacers 77.

A thermal oxidation process can be performed to convert physically exposed surface portions of various semiconductor materials into semiconductor oxide portions. Specifically, physically exposed surface portions of the source contact layer 114, the upper source-level material layer 116, and the source-select-level conductive layer 118 (if present) are converted into thermal semiconductor oxide material portions. As used herein, a “thermal semiconductor oxide” refers to a material that is formed by thermal oxidation of a semiconductor material. Unlike a semiconductor oxide material formed by chemical vapor deposition, thermal semiconductor oxide materials do not include carbon or hydrogen above a trace level unless the semiconductor material from which the semiconductor oxide material is derived includes carbon prior to a thermal oxidation process.

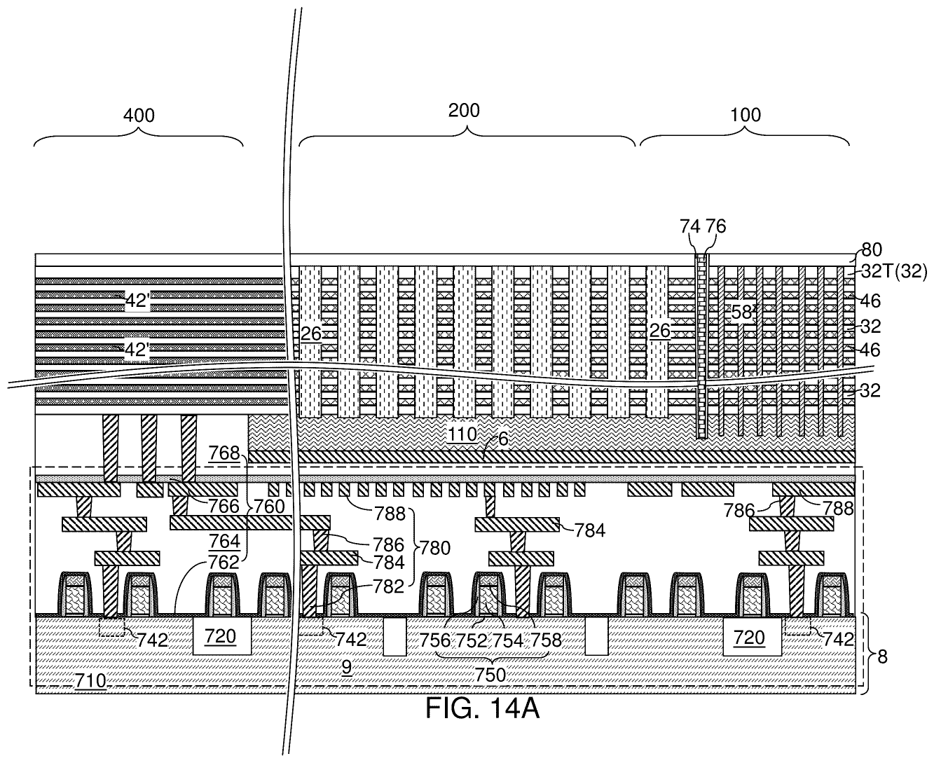

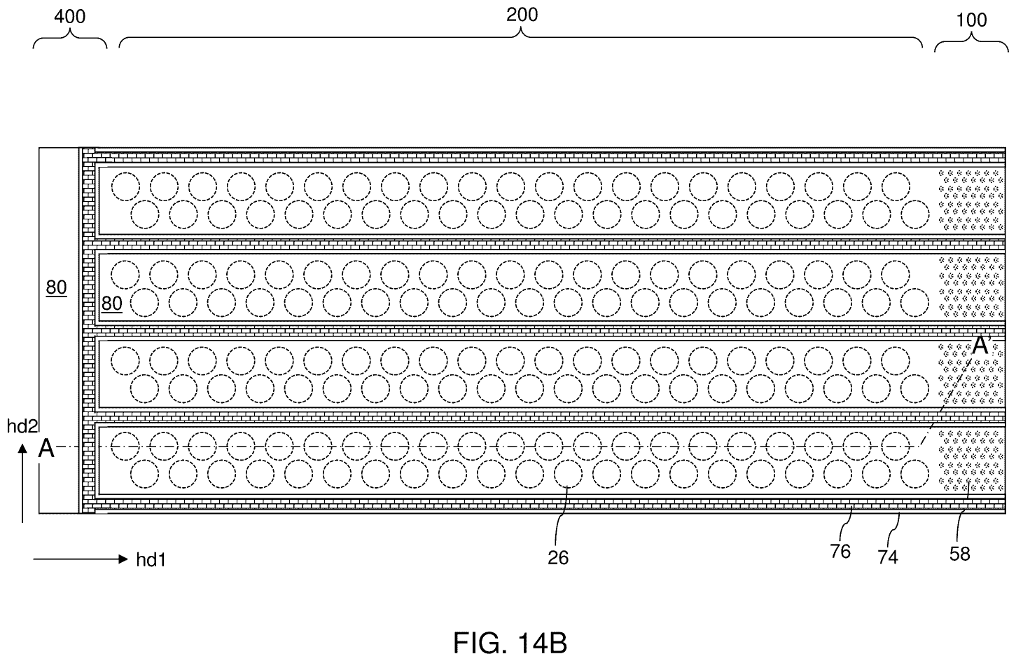

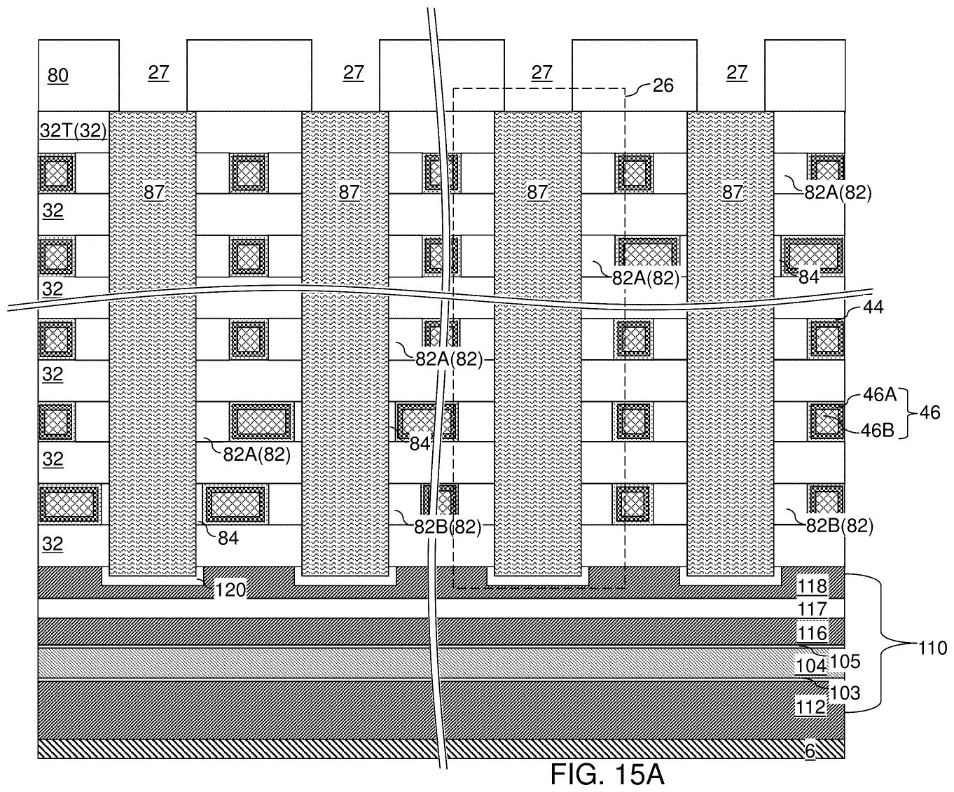

The thermal oxidation process forms a semiconductor oxide plate 122 at the bottom of each backside trench 79 and semiconductor oxide rails 124 on sidewalls of the source-select-level conductive layer 118. The semiconductor oxide rails 124 are not illustrated in FIG. 14 for clarity. The semiconductor oxide plate 122 includes various thermal semiconductor oxide material portions formed by thermal conversion of surface portions of the source contact layer 114 and the upper source-level material layer 116.

The layer stack including the lower source-level material layer 112, the source contact layer 114, and the upper source-level material layer 116 constitutes a source layer (112, 114, 116), which is a buried source layer that functions as a common source region that is connected each of the vertical semiconductor channels 60 and has a doping of the second conductivity type. The average dopant concentration in the buried source layer (112, 114, 116) can be in a range from 5.0×10¹⁹/cm³ to 2.0×10²¹/cm³, although lesser and greater dopant concentrations can also be employed.

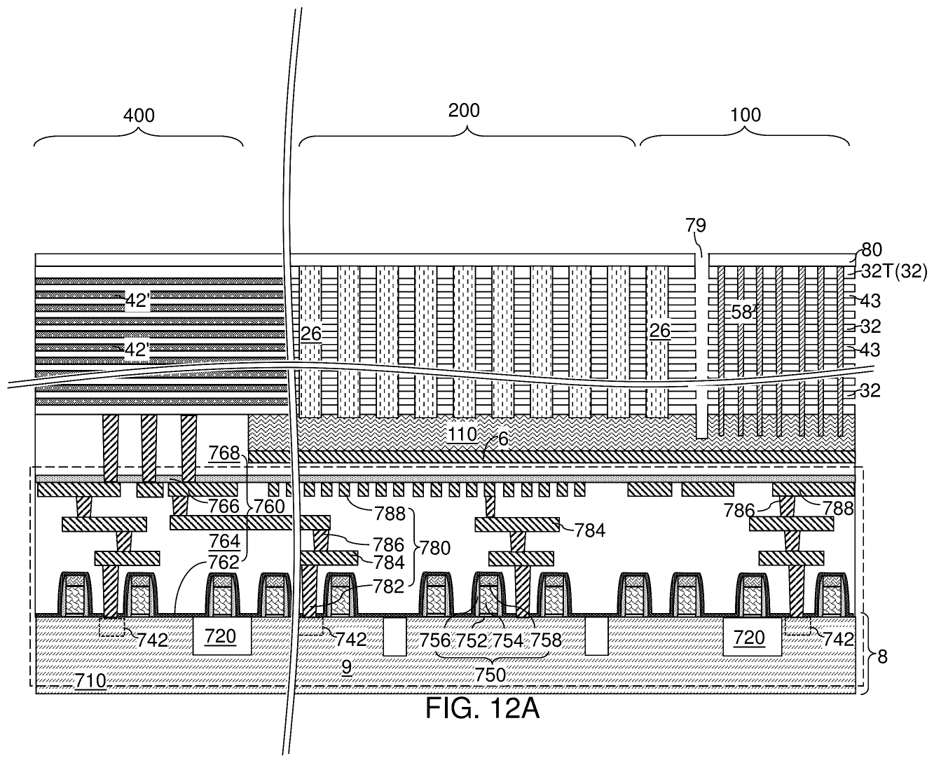

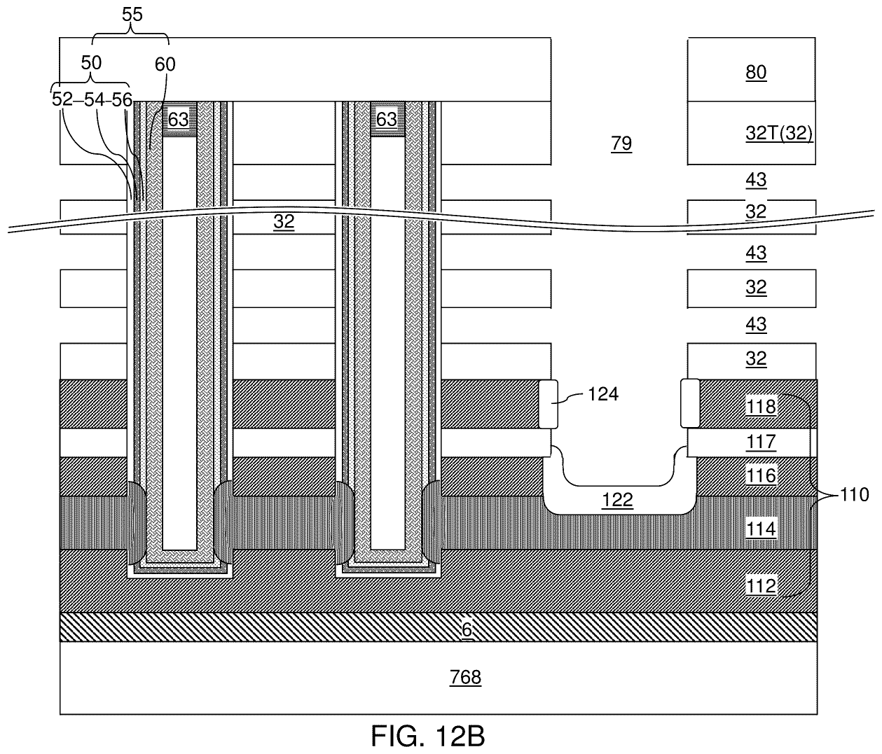

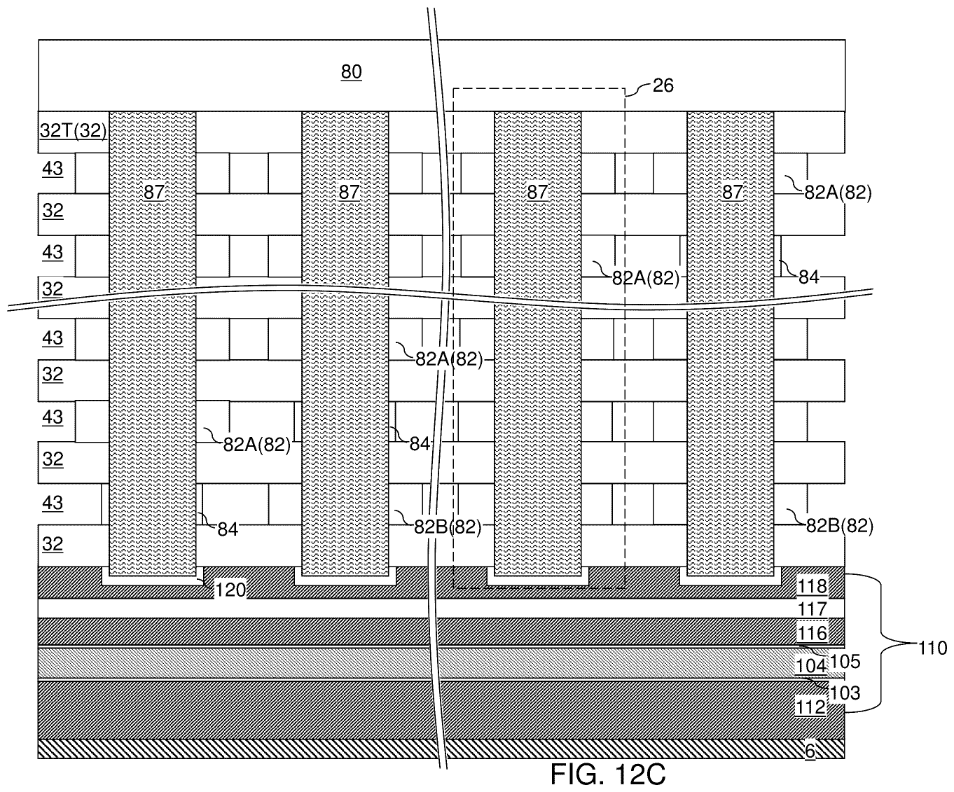

Referring to FIG. 12A-12C, an etchant that selectively etches the materials of the sacrificial material layers 42 with respect to the materials of the insulating layers 32 and the material of the outermost layer of the memory films 50 can be introduced into the backside trenches 79, for example, employing an isotropic etch process. For example, the sacrificial material layers 42 can include silicon nitride, the materials of the insulating layers 32 and the material of the outermost layer of the memory films 50 can include silicon oxide materials. Backside recesses 43 are formed in volumes from which the sacrificial material layers 42 are removed.

The isotropic etch process can be a wet etch process employing a wet etch solution, or can be a gas phase (dry) etch process in which the etchant is introduced in a vapor phase into the backside trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, carbon, and various other materials employed in the art.

Each of the backside recesses 43 can be a laterally extending cavity having a lateral dimension that is greater than the vertical extent of the cavity. In other words, the lateral dimension of each of the backside recesses 43 can be greater than the height of the respective backside recess 43. Each of the backside recesses 43 can laterally extend substantially parallel to the top surface of the substrate 8. A backside recess 43 can be vertically bounded by a top surface of an underlying insulating layer 32 and a bottom surface of an overlying insulating layer 32. In one embodiment, each of the backside recesses 43 can have a uniform height throughout.

Unetched remaining portions of the sacrificial material layers 42 may remain in the connection region 400. The remaining portions of the sacrificial material layers 42 in the connection region 400 comprise dielectric material layers, and may be hereafter referred to as dielectric material plates 42′.

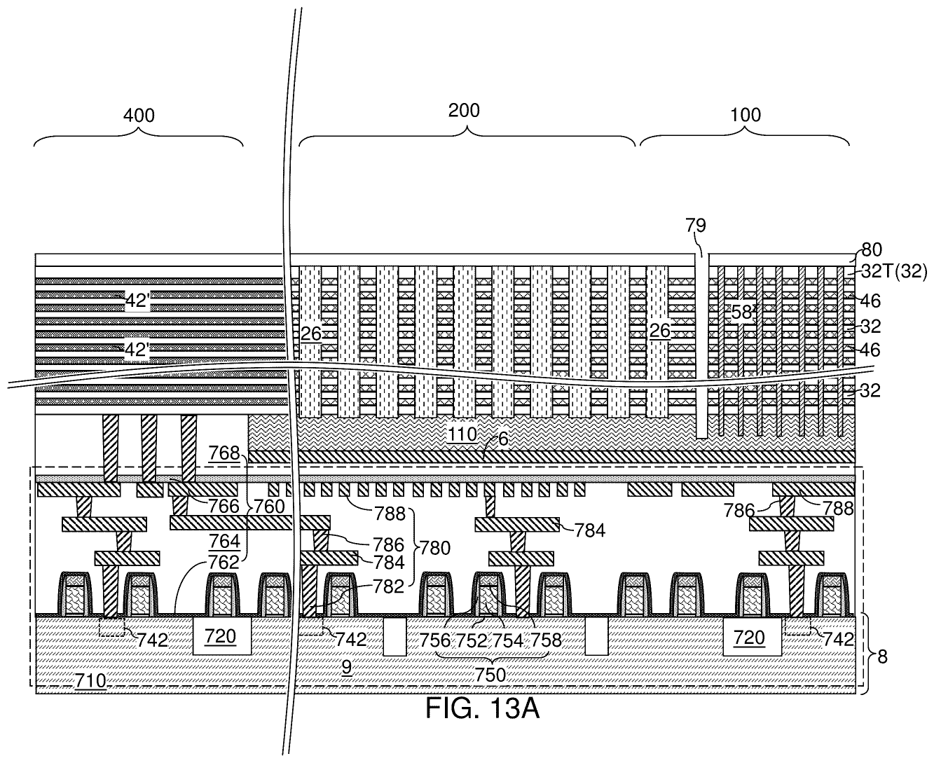

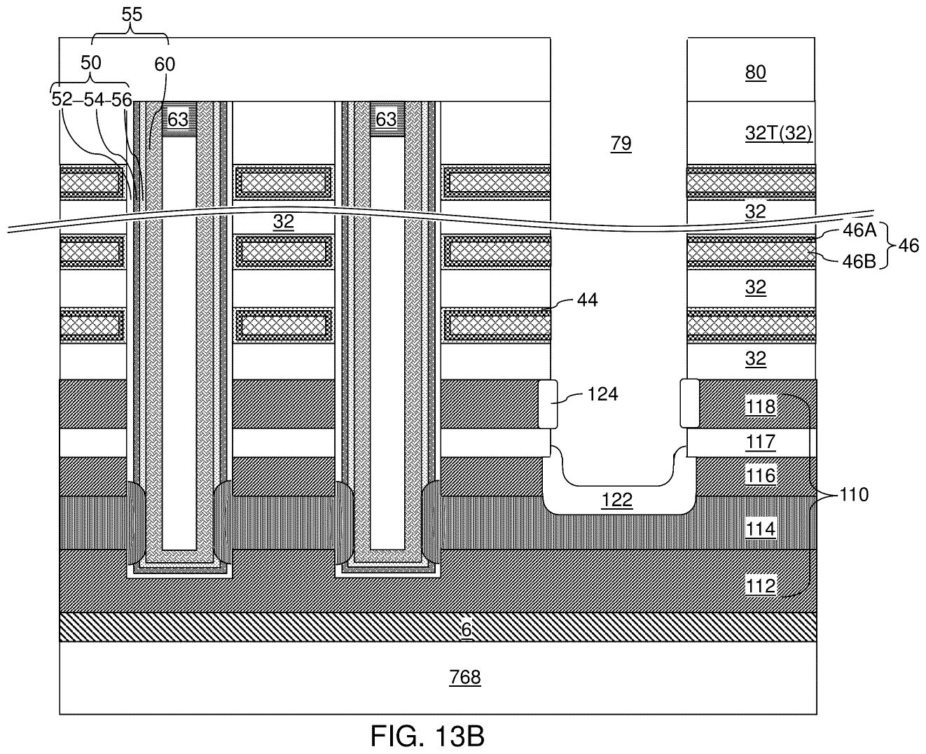

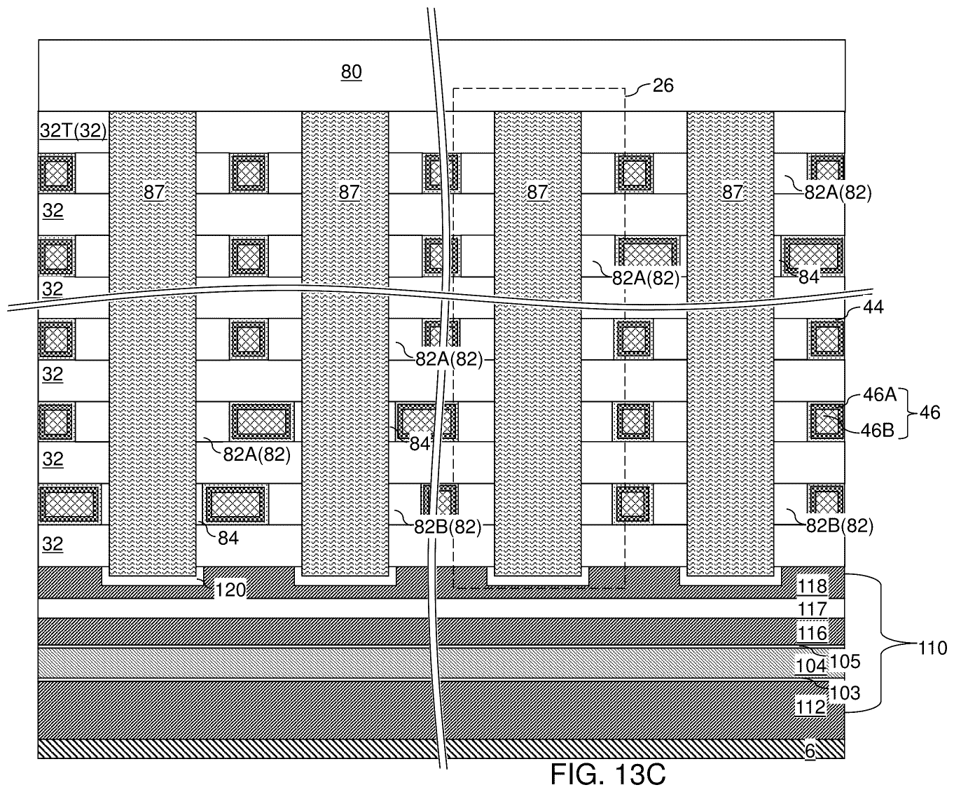

Referring to FIGS. 13A-13C, a backside blocking dielectric layer 44 can be optionally deposited in the backside recesses 43 and the backside trenches 79 and over the contact-level dielectric layer 80. The backside blocking dielectric layer 44 comprises a dielectric metal oxide, such as aluminum oxide, a dielectric oxide of at least one transition metal element, a dielectric oxide of at least one Lanthanide element, a dielectric oxide of a combination of aluminum, at least one transition metal element, and/or at least one Lanthanide element. Alternatively or additionally, the backside blocking dielectric layer 44 can include a silicon oxide layer. The backside blocking dielectric layer 44 can be deposited by a conformal deposition method such as chemical vapor deposition or atomic layer deposition. The backside blocking dielectric layer 44 is formed on the sidewalls of the backside trenches 79, horizontal surfaces and sidewalls of the insulating layers 32, the portions of the sidewall surfaces of the memory opening fill structures 58 that are physically exposed to the backside recesses 43. A backside cavity is present within the portion of each backside trench 79 that is not filled with the backside blocking dielectric layer 44.

A metallic barrier layer 46A can be deposited in the backside recesses 43, peripheral portions of the backside trenches 79, and over the contact-level dielectric layer 80. The metallic barrier layer 46A includes an electrically conductive metallic material that can function as a diffusion barrier layer and/or adhesion promotion layer for a metallic fill material to be subsequently deposited. The metallic barrier layer 46A can include a conductive metallic nitride material such as TiN, TaN, MON, WN, or a stack thereof, or can include a conductive metallic carbide material such as TiC, TaC, WC, or a stack thereof. In one embodiment, the metallic barrier layer 46A can be deposited by a conformal deposition process such as chemical vapor deposition (CVD) or atomic layer deposition (ALD). The thickness of the metallic barrier layer 46A can be in a range from 2 nm to 8 nm, such as from 3 nm to 6 nm, although lesser and greater thicknesses can also be employed. In one embodiment, the metallic barrier layer 46A can consist essentially of a conductive metal nitride such as TiN.

A metal fill material is deposited in the plurality of backside recesses 43, on the sidewalls of the at least one the backside trench 79, and over the top surface of the contact-level dielectric layer 80 to form a metallic fill material layer 46B. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer 46B can consist essentially of at least one elemental metal. The at least one elemental metal of the metallic fill material layer 46B can be selected, for example, from tungsten, cobalt, ruthenium, titanium, and tantalum. In one embodiment, the metallic fill material layer 46B can consist essentially of a single elemental metal. In one embodiment, the metallic fill material layer 46B can be deposited employing a fluorine-containing precursor gas such as WF₆. In one embodiment, the metallic fill material layer 46B can be a tungsten layer including a residual level of fluorine atoms as impurities. The metallic fill material layer 46B is spaced from the insulating layers 32 and the memory opening fill structures 58 by the metallic barrier layer 46A, which is a metallic barrier layer that blocks diffusion of fluorine atoms therethrough.

An etch back process can be performed to remove portions of the metallic fill material layer 46B and the metallic barrier layer 46A from inside the backside trenches 79 and from above the contact-level dielectric layer 80. The etch back process may comprise an isotropic etch process and/or an anisotropic etch process. Each combination of a remaining portion of the metallic barrier layer 46A and a remaining portion of the metallic fill material layer 46B that remain in a respective backside recess 43 constitutes an electrically conductive layer 46. The backside blocking dielectric layer 44 may or may not remain in the backside trenches 79.

Each electrically conductive layer 46 includes a portion of the metallic barrier layer 46A and a portion of the metallic fill material layer 46B that are located between a vertically neighboring pair of dielectric material layers such as a pair of insulating layers 32. Each sacrificial material layer 42 can be replaced with an electrically conductive layer 46. Generally, at least one alternating stack (32, 46) of insulating layers 32 and electrically conductive layers 46 can be formed over the semiconductor substrate 8.

Referring to FIGS. 14A and 14B, an insulating material layer can be formed in the backside trenches 79 and over the contact-level dielectric layer 80 by a conformal deposition process. Exemplary conformal deposition processes include, but are not limited to, chemical vapor deposition and atomic layer deposition. The insulating material layer includes an insulating material such as silicon oxide, silicon nitride, a dielectric metal oxide, an organosilicate glass, or a combination thereof. In one embodiment, the insulating material layer can include silicon oxide. The insulating material layer can be formed, for example, by low pressure chemical vapor deposition (LPCVD) or atomic layer deposition (ALD). The thickness of the insulating material layer can be in a range from 1.5 nm to 60 nm, although lesser and greater thicknesses can also be employed.

An anisotropic etch is performed to remove horizontal portions of the insulating material layer from above the contact-level dielectric layer 80 and at the bottom of each backside trench 79. Each remaining portion of the insulating material layer constitutes an insulating spacer 77. A backside cavity is present within a volume surrounded by each insulating spacer 74.

A backside contact via structure 76 can be formed within each backside cavity. Each backside contact via structure 76 can fill a respective cavity. Each contact via structures 76 can be formed by depositing at least one conductive material in a remaining unfilled volume (i.e., a backside cavity) of the backside trenches 79. For example, the at least one conductive material can include a conductive liner and a conductive fill material portion. The conductive liner can include a conductive metallic liner such as TiN, TaN, MON, WN, TiC. TaC, WC, an alloy thereof, or a stack thereof. The thickness of the conductive liner can be in a range from 3 nm to 30 nm, although lesser and greater thicknesses can also be employed. The conductive fill material portion can include a metal or a metallic alloy. For example, the conductive fill material portion can include W, Cu, Al, Co, Ru, Ni, an alloy thereof, or a stack thereof.

The at least one conductive material can be planarized employing the contact-level dielectric layer 80 overlying the alternating stack (32, 46) as a stopping layer. If chemical mechanical planarization (CMP) process is employed, the contact-level dielectric layer 80 can be employed as a CMP stopping layer. Each remaining continuous portion of the at least one conductive material in the backside trenches 79 constitutes a backside contact via structure 76 (e.g., a source contact).

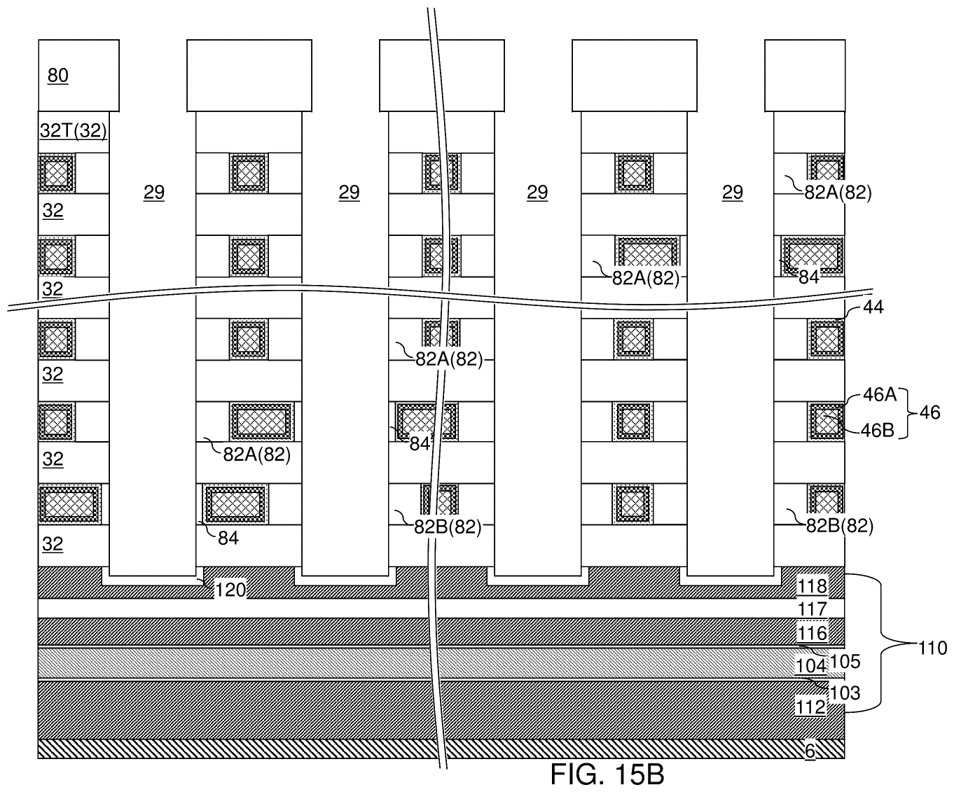

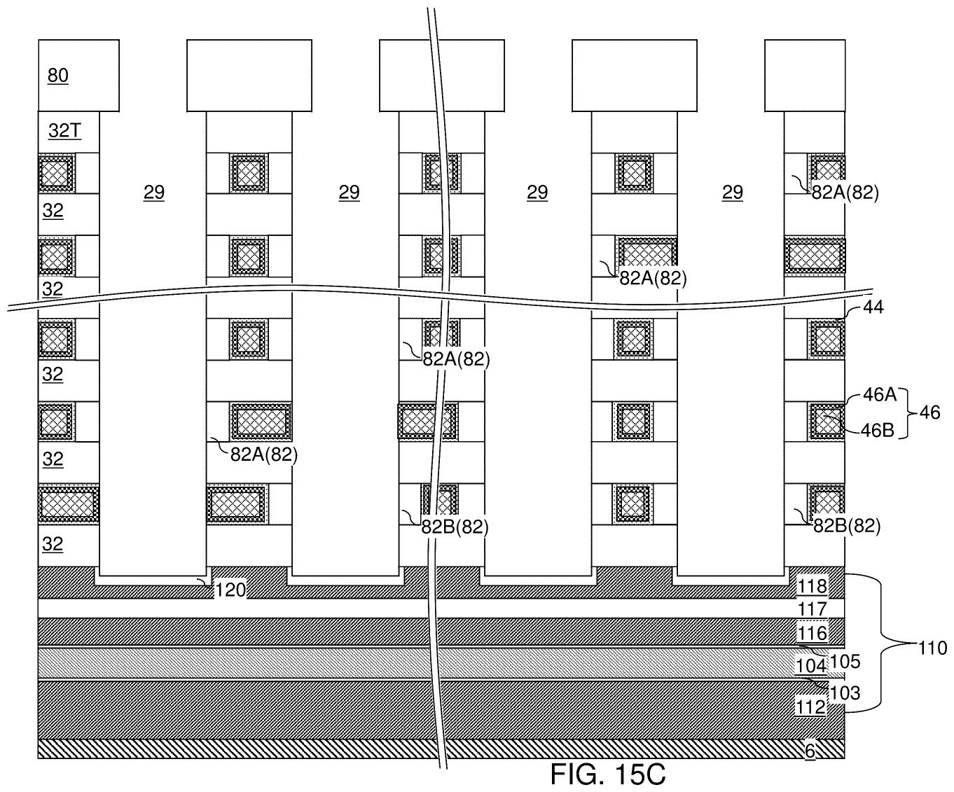

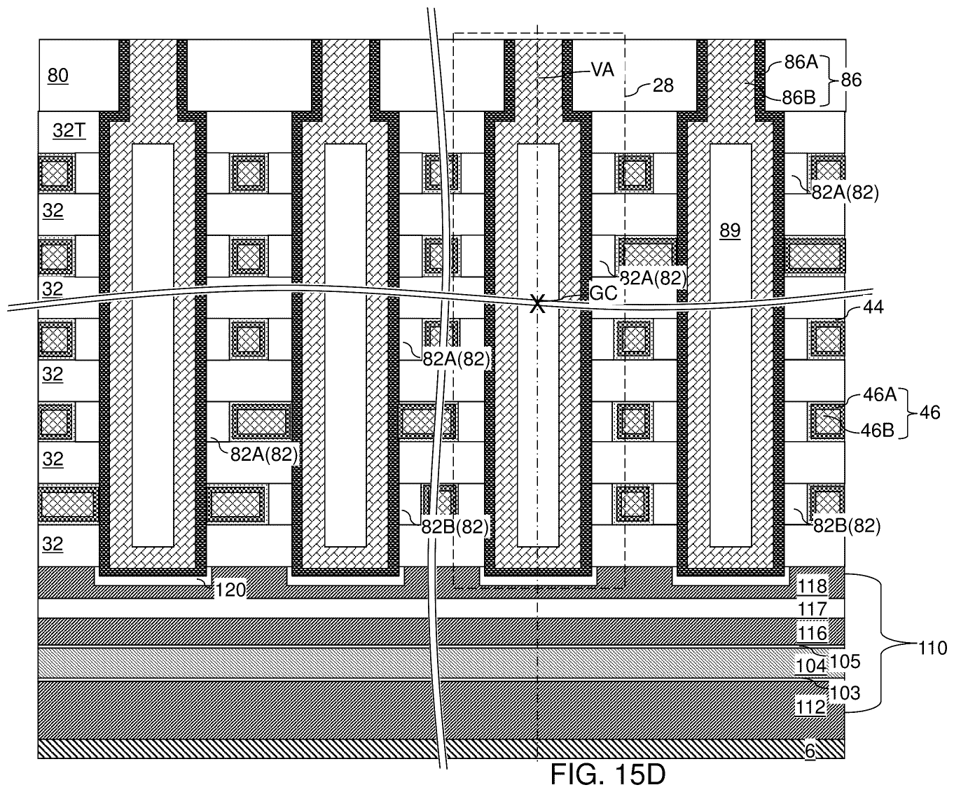

FIGS. 15A-15D are sequential vertical cross-sectional views of the contact region 200 during replacement of the in-process layer contact assemblies 26 with layer contact assemblies 28 according to the first embodiment of the present disclosure.

Referring to FIG. 15A, a photoresist layer (not shown) can be applied over the contact-level dielectric layer 80, and can be lithographically patterned to form openings over the in-process layer contact assemblies 26. An anisotropic etch process may be performed to transfer the pattern of the openings in the photoresist layer through the contact-level dielectric layer 80. An array of openings 27 can be formed through the contact-level dielectric layer 80. A top surface of a sacrificial contact opening fill structure 87 can be physically exposed at the bottom of each opening 27 through the contact-level dielectric layer 80.

Referring to FIG. 15B, a selective etch process can be performed to remove the sacrificial contact opening fill structures 87 selective to the contact-level dielectric layer 80, the insulating layers 32, the annular dielectric spacers 82, the annular sacrificial spacers 84, and the semiconductor oxide plates 120. In an illustrative example, if the sacrificial contact opening fill structures 87 comprise amorphous silicon, then a wet etch process employing hot trimethyl-2 hydroxyethyl ammonium hydroxide (“hot TMY”) or tetramethyl ammonium hydroxide (TMAH) can be employed to remove the sacrificial contact opening fill structures 87. Alternatively, if the sacrificial contact opening fill structures 87 comprise a carbon material, then the sacrificial contact opening fill structures 87 can be removed by ashing. Contact openings 29 can be formed within the volumes of the contact openings 85.

Referring to FIG. 15C, at least one isotropic etch process can be performed to remove the annular sacrificial spacers 84 and vertically-extending portions of the backside blocking dielectric layers 44 that are located adjacent to the annular sacrificial spacers 84. For example, if the annular sacrificial spacers 84 comprise silicon oxide and if the backside blocking dielectric layers 44 comprise aluminum oxide, then a wet etch process employing dilute hydrofluoric acid is used to remove the annular sacrificial spacers 84 and vertical portions of the backside blocking dielectric layers 44 that were proximal to the annular sacrificial spacers 84. Alternatively, a NH:OH:H₂O₂:H₂O based etch may be used to remove the exposed vertical portions of the backside blocking dielectric layers 44 after removal of the annular sacrificial spacers 84.

In one embodiment, inner portions of the annular dielectric spacers 82 can be collaterally removed around each contact opening 29 during removal of the annular sacrificial spacer 84. In one embodiment, the insulating layers 32, the contact-level dielectric layer 80, the annular dielectric spacers 82, and the semiconductor oxide plates 120 may be collaterally recessed during the at least one isotropic etch process that removes the annular sacrificial spacers 84 and the vertical portions of the backside blocking dielectric layers 44.

A cylindrical sidewall of an electrically conductive layer 46 can be physically exposed around each volume from which a combination of an annular sacrificial spacer 84 and a vertical cylindrical portion of a backside blocking dielectric layer 44 is removed. Each contact opening 29 can be laterally expanded by the at least one isotropic etch process. Each contact opening 29 can be laterally bounded by a respective generally-cylindrical sidewall, which may have a straight vertical cross-sectional profile or a laterally-undulating vertical cross-sectional profile depending on whether physically exposed cylindrical sidewalls of the insulating layers 32 are vertically coincident with inner cylindrical sidewalls of the annular dielectric spacers 82. Generally, the inner cylindrical sidewalls of the annular dielectric spacers 82 may be located at, inside or outside a vertical cylindrical vertical plane including physically exposed cylindrical sidewalls of the insulating layers 32 around each contact opening 29. Generally, a cylindrical sidewall of one of the electrically conductive layers 46 can be physically exposed at each level from which an annular sacrificial spacer 84 is removed. In one embodiment, each of the electrically conductive layers 46 may be physically exposed within each group of cylindrical openings 29 located in a memory block between a neighboring pair of backside trench fill structures (74, 76) located within a respective neighboring pair of lengthwise backside trenches 79L.

Referring to FIG. 15D, at least one conductive material can be deposited in the contact openings 29. The at least one conductive material may comprise a metallic barrier material and a metallic fill material. The metallic barrier material may comprise a metallic nitride material such as TiN, TaN, MON and/or WN and/or a metallic carbide material such as TiC. TaC, and/or WC. The metallic fill material may comprise W, Ti, Ta, Ru, Co, Mo, Cu, etc. The at least one conductive material may be deposited by chemical vapor deposition, physical vapor deposition, electroplating, electroless plating, or combinations thereof. Excess portions of the at least one conductive material can be removed from above the horizontal plane including the top surface of the contact-level dielectric layer 80 by performing a planarization process, which may employ a chemical mechanical polishing (CMP) process or a recess etch process. Each remaining portion of the at least one conductive material filling a respective contact opening 29 constitutes a contact via structure that contacts a vertical cylindrical sidewall of a respective electrically conductive layer 46. As such, each contact via structure is referred to as a side-contact via structure 86. Each side-contact via structure 86 vertically extends through each layer within the at least one alternating stack (32, 46) and contacts a sidewall of one of the electrically conductive layers 46. In one embodiment, each side-contact via structure 86 can contact a cylindrical sidewall one of the electrically conductive layers 46, and may be electrically isolated from all other electrically conductive layers 46 by the annular dielectric spacers 82.

In one embodiment, each side-contact via structure 86 may comprise a metallic barrier layer 86A comprising a metallic barrier material, and a metallic fill material portion 86B comprising a metallic fill material. In one embodiment, one, a plurality or each of the side-contact via structures 86 may comprise an encapsulated cavity (i.e., air gap) 89 that is free of any solid phase material therein. Alternatively, at least one etch back process may be employed in conjunction with multiple deposition processes to prevent formation of, or to reduce the sizes of, the encapsulated cavities 89. Each contiguous combination of a side-contact via structure 86 and a vertical stack of annular dielectric spacers 82 is herein referred to as a layer contact assembly 28.

In one embodiment, an entirety of an interface between one, a plurality and/or each of the side-contact via structures 86 and a respective one of the electrically conductive layers 46 may be located within a respective cylindrical vertical plane. In one embodiment, the side-contact via structures 86 do not contact any horizontal surface of the electrically conductive layers 46.

In one embodiment, a vertical stack of annular dielectric spacers 82 may laterally surround each side-contact via structure 86. For each side-contact via structure 86, each electrically conductive layer 46 within the at least one alternating stack (32, 46) except a respective one of the electrically conductive layers 46 can be laterally spaced from and can be electrically isolated from the side-contact via structure 86 by a respective one of the annular dielectric spacers 82. In one embodiment, for each side-contact via structure 86, each of the annular dielectric spacers 82 comprises a respective outer cylindrical sidewall that is laterally offset outward from a respective inner cylindrical sidewall by a respective lateral offset distance that is independent of an azimuthal angle from a vertical axis VA passing through a geometrical center GC of the side-contact via structure 86. All lateral offset distances of the annular dielectric spacers 82 can be the same. A geometrical center of an element refers to the center of gravity of a hypothetical object occupying the same volume as the element and having a uniform density throughout.

In one embodiment, for each side-contact via structure 86, each of the insulating layers 32 within the at least one alternating stack (32, 46) comprises a respective vertical cylindrical sidewall that contacts the side-contact via structure 86.

In one embodiment, backside blocking dielectric layers 44 can be located between each vertically neighboring pair of an insulating layer 32 and an electrically conductive layer 46 within the at least one alternating stack (32, 46). In one embodiment, each side-contact via structure 86 can be in contact with two cylindrical surface segments of horizontally extending backside blocking dielectric layers 44. Each of the two cylindrical surface segments may have a height that is the same as the thickness of the backside blocking dielectric layers 44.

In one embodiment, each of the electrically conductive layers 46 comprises a respective combination of a metallic barrier liner 46A and a metallic fill material portion 46B. In one embodiment, each side-contact via structure 86 may be in contact with a metallic barrier liner 46A of a respective one of the electrically conductive layers 46, and is laterally spaced from a metallic fill material portion 46B of the respective one of the electrically conductive layers 46 by the respective metallic barrier liner 46A.

Each side-contact via structure 86 may be laterally surrounded by a respective vertical stack of annular dielectric spacers 82. The side-contact via structure 86 is in contact with an inner cylindrical sidewall of each annular dielectric spacer 82 within the vertical stack of annular dielectric spacers 82.

Each side-contact via structure 86 can vertically extend through each layer within the at least one alternating stack (32, 46) and can contact a sidewall of one respective electrically conductive layer 46.

In one embodiment, at least one semiconductor material layer (such as the source-level material layers (112, 114, 116)) may be located between the substrate 8 and the at least one alternating stack (32, 46). Alternatively, if the lower-level metal interconnect structures 780 and the source-level material layers 110 are omitted, then may the bottom of the side-contact via structure 86 may be located in an upper portion of the substrate. In one embodiment, each of the vertical semiconductor channels 60 comprises an end portion that is electrically connected to the at least one semiconductor material layer 112 (e.g., to a semiconductor source layer or source line). The sidewall-contact via structures 86 may be electrically isolated from the at least one semiconductor material layer (112, 114, 116) (e.g., from the source layer) by semiconductor oxide plates 120. In one embodiment, the at least one semiconductor material layer (112, 114, 116) comprises a layer stack of source-level material layers 110 including a lower source-level material layer 112, a source contact layer 114 contacting each of the vertical semiconductor channels 60, and an upper source-level material layer 116.

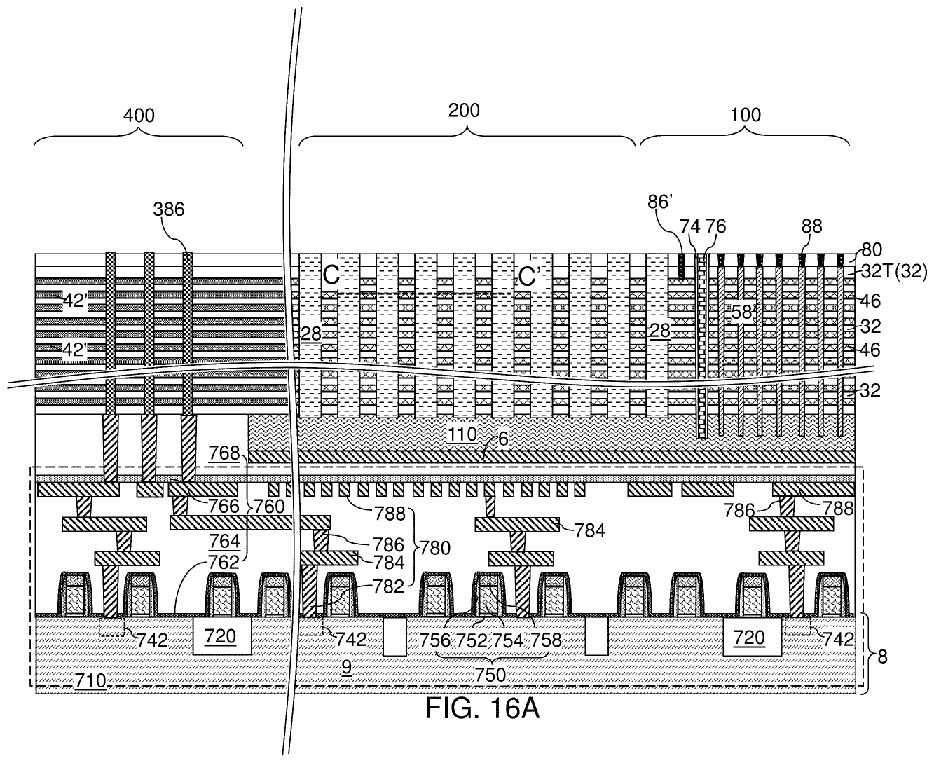

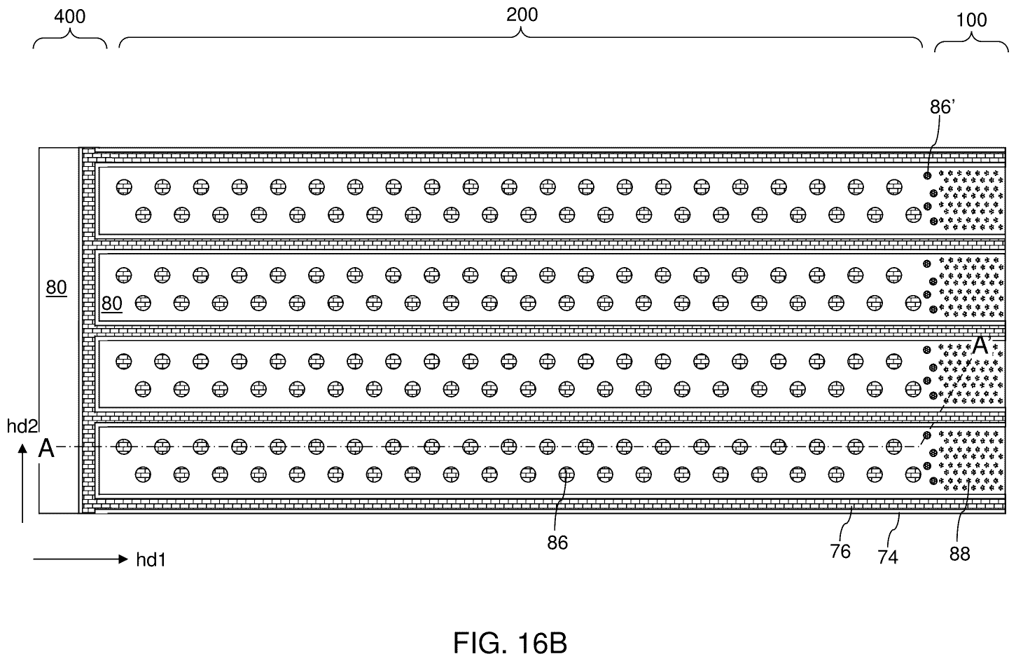

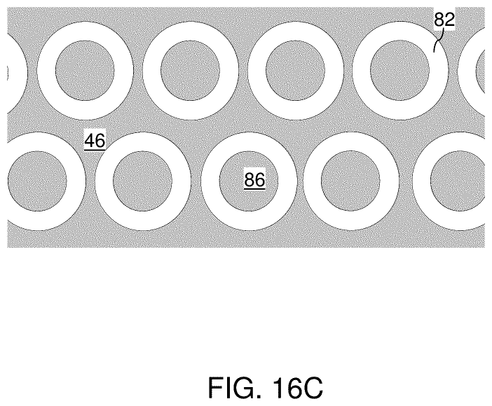

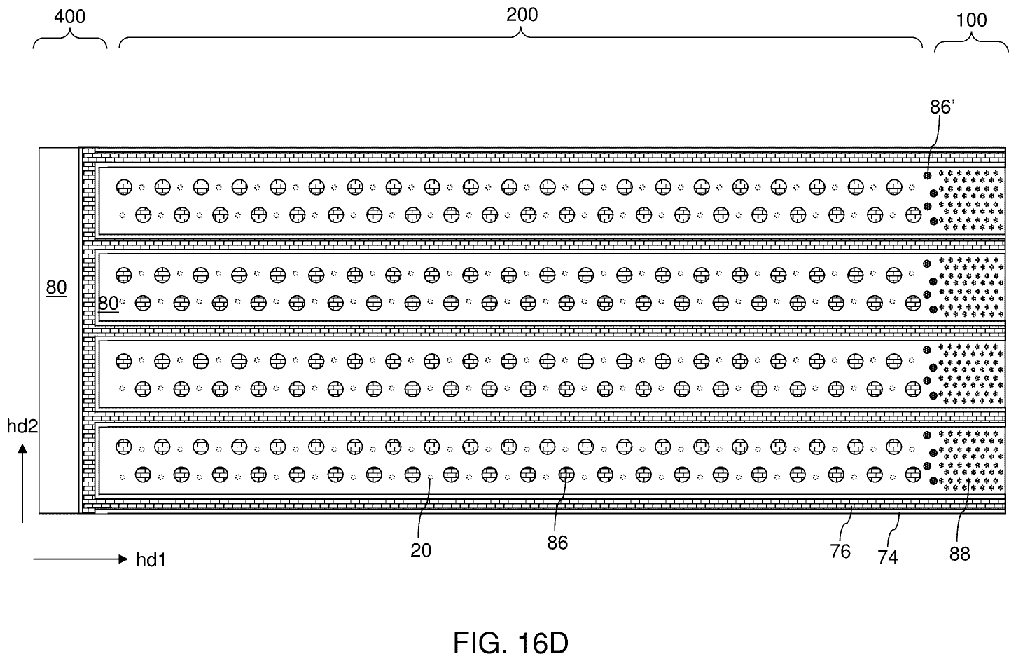

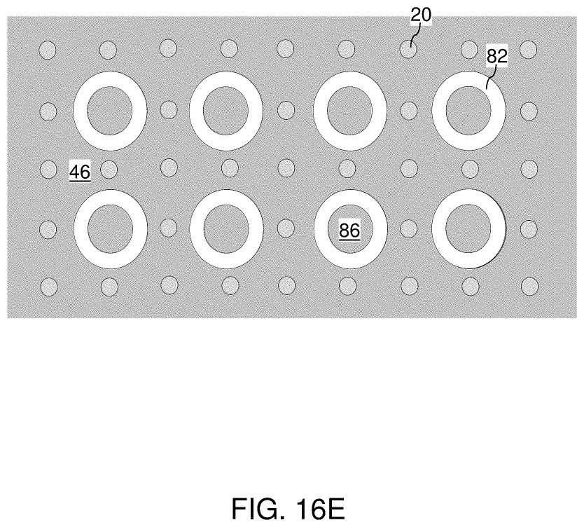

Referring to FIGS. 16A and 16B, additional conductive via structures (88, 86′, 386) can be formed. The additional conductive via structures (88, 86′, 386) may comprise, for example, drain contact via structures 88 that are formed through the contact-level dielectric layer 80 directly on a top surface of a respective one of the drain regions 63, optional drain-select-level contact via structures 86′ that may be formed on drain side select gate electrodes (which may be a divided strip of one or more topmost electrically conductive layers 46), and connection via structures 386 that may be formed in the peripheral region through as stack of dielectric material plates 42′ (which are remaining portions of the sacrificial material layers 42) and through each of the insulating layers 32.

In one configuration of the first exemplary structure shown in FIGS. 16B and 16C, there are no support pillar structures in the contact region 200. Instead, the sacrificial contact opening fill structure 87 keeps the insulating layers 32 vertically separated from each other after removal of the sacrificial material layers 42 and formation of the backside recesses 43.

In an alternative embodiment shown in FIGS. 16D and 16E, support pillar structures 20 may be formed in the contact region 200 between neighboring pairs of side-contact via structures 86. Each support pillar structures 20 may comprise a same set of materials as a memory opening fill structure 58, and may be formed during the processing steps that form the memory opening fill structures 58. Alternatively, the support pillar structures 20 may comprise an insulating material such as silicon oxide, and may be formed prior to formation of the contact-level dielectric layer 80. Generally, the support pillar structures 20 can provide additional structural support to the insulating layers 32 and the in-process layer contact assemblies 26 during replacement of the sacrificial material layers 42 with electrically conductive layers 46.

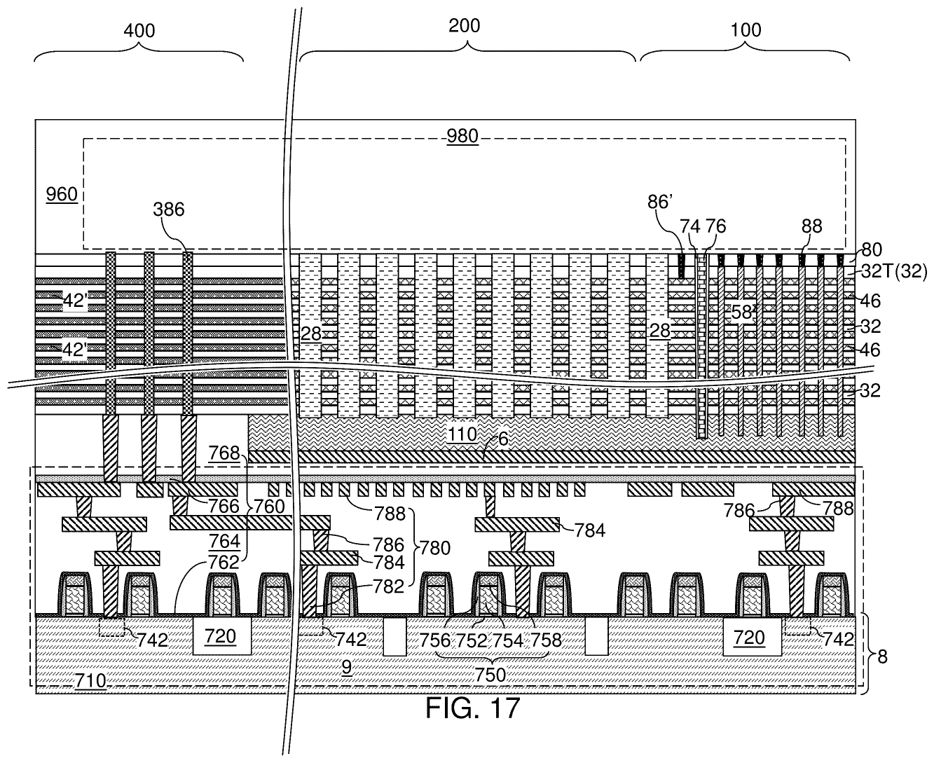

Referring to FIG. 17, bit lines and upper metal interconnect structures 980 and upper dielectric material layers 960 can be formed above the contact-level dielectric layer 80 to provide electrical connections to and/or between the drain contact via structures 88, the side-contact via structures 86, the connection via structures 386, and the optional drain-select-level contact via structures 86′.

According to another aspect of the present disclosure, a second exemplary structure can be derived from the first exemplary structure by employing multi-tier structures including multiple alternating stacks of insulating layers 32 and sacrificial material layers 42.

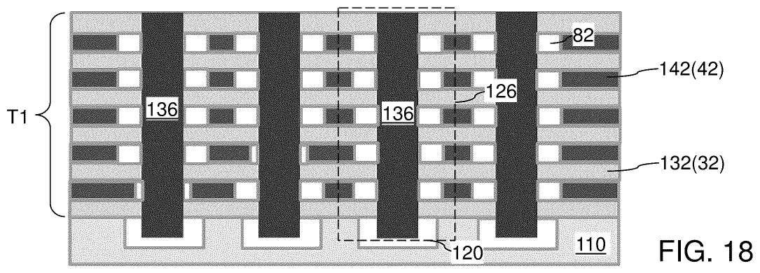

Referring to FIG. 18, the second exemplary structure is illustrated after formation of a first alternating stack (132, 142) of first insulating layers 132 and first sacrificial material layers 142, first-tier memory openings (not shown), first-tier sacrificial memory opening fill structures (not shown), first-tier backside trenches (not shown), first-tier sacrificial backside trench fill structures (not shown), and first-tier in-process layer contact assemblies 126. The first insulating layers 132 are a first subset of insulating layers 32, and the first sacrificial material layers 142 are a first subset of sacrificial material layers 42. The first-tier in-process layer contact assemblies 126 can be formed in the same manner as the in-process layer contact assemblies 26 described above. In this case, the sacrificial structures that fill first-tier contact opening are herein referred to as first-tier sacrificial contact opening fill structure 136. A first-tier structure T1 can be formed.

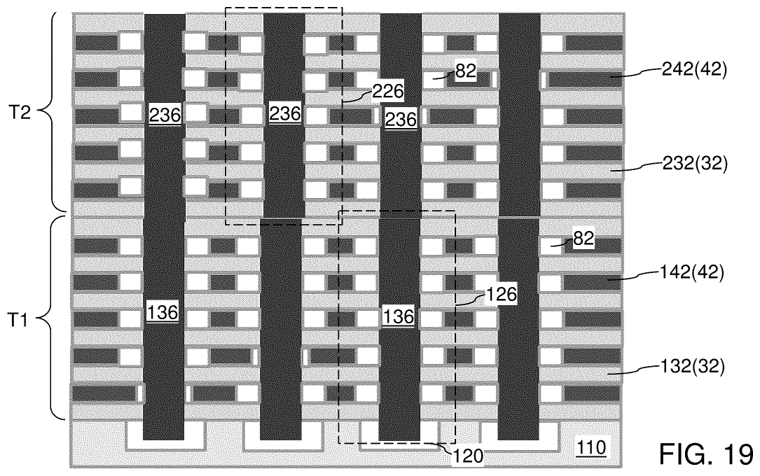

Referring to FIG. 19, the second exemplary structure is illustrated after formation of a second alternating stack (232, 242) of second insulating layers 232 and second sacrificial material layers 242, second-tier memory openings (not shown), second-tier sacrificial memory opening fill structures (not shown), second-tier backside trenches (not shown), second-tier sacrificial backside trench fill structures (not shown), and second-tier in-process layer contact assemblies 226. The second insulating layers 232 are a second subset of insulating layers 32, and the second sacrificial material layers 242 are a second subset of sacrificial material layers 42. The second-tier in-process layer contact assemblies 226 can be formed in the same manner as the in-process layer contact assemblies 26 described above. In this case, the sacrificial structures that fill second-tier contact opening are herein referred to as second-tier sacrificial contact opening fill structure 236. A second-tier structure T2 can be formed.

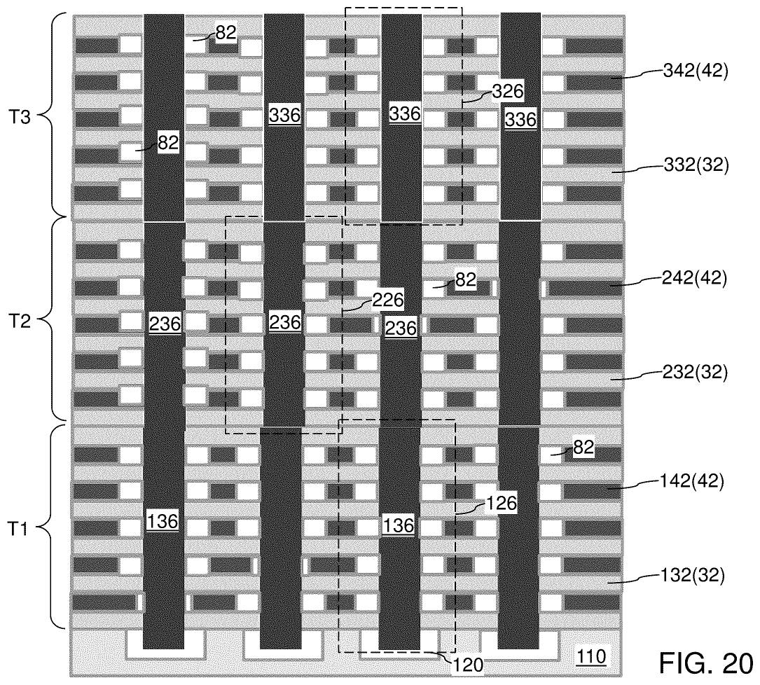

Referring to FIG. 20, the second exemplary structure is illustrated after formation of an optional third alternating stack (332, 342) of third insulating layers 332 and third sacrificial material layers 342, memory opening fill structures (not shown), and third-tier in-process layer contact assemblies 326. The third insulating layers 332 are a third subset of insulating layers 32, and the third sacrificial material layers 342 are a third subset of sacrificial material layers 42. The third-tier in-process layer contact assemblies 326 can be formed in the same manner as the in-process layer contact assemblies 26 described above. In this case, the sacrificial structures that fill third-tier contact opening are herein referred to as third-tier sacrificial contact opening fill structure 336. A third-tier structure T3 can be formed.

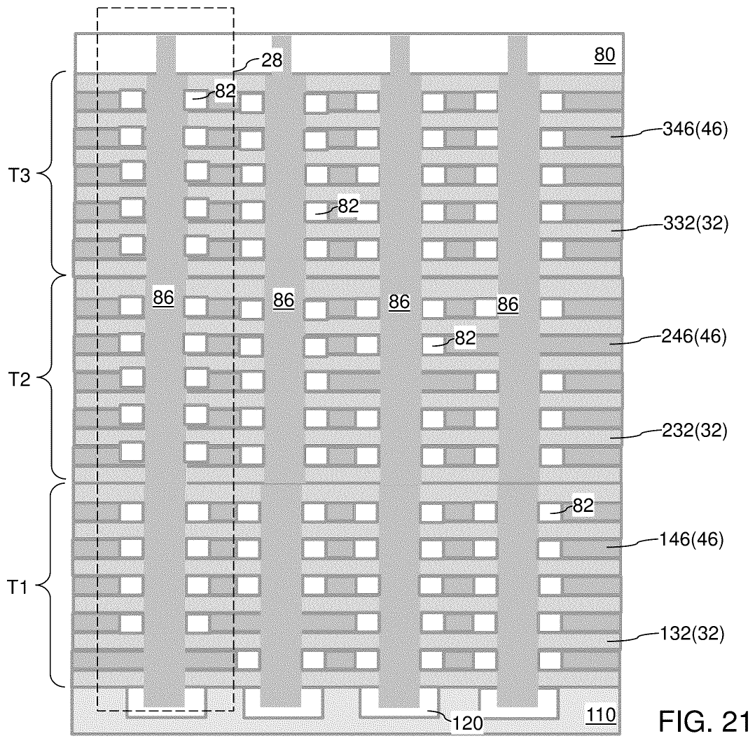

Referring to FIG. 21, the processing steps described with reference to FIGS. 8-17 can be performed with any needed changes to form backside trenches vertically extending through the multiple tier structures (T1, T2, T3) and into the in-process source-level material layers 110′, to replace the in-process source-level material layers 110′ with source-level material layers 110, to replace the first, second, and third sacrificial material layers (142, 242, 342) with first, second, and third electrically conductive layers (146, 146, 346), respectively, to replace the combination of the third-tier in-process layer contact assemblies 326, the second-tier in-process layer contact assemblies 226, and the first-tier in-process layer contact assemblies 126 with layer contact assemblies 28, and to form additional contact via structures (not shown) and upper metal interconnect structures and upper dielectric material layers.

Referring to all drawings and according to various embodiments of the present disclosure, a memory device comprises: at least one alternating stack (32, 46) of insulating layers 32 and electrically conductive layers 46; memory openings 49 vertically extending through each layer within the at least one alternating stack (32, 46); memory opening fill structures 58 located in the memory openings 49 and comprising a respective vertical semiconductor channel 60 and a respective vertical stack of memory elements; and an electrically conductive side-contact via structure 86 vertically extending through each layer within the at least one alternating stack (32, 46) and contacting a sidewall of one of the electrically conductive layers 46.

In one embodiment, an entirety of an interface between the side-contact via structure 86 and the one of the electrically conductive layers 46 is located within a cylindrical vertical plane.

In one embodiment, the memory device comprises a vertical stack of annular dielectric spacers 82 laterally surrounding the side-contact via structure 86, wherein each electrically conductive layer 46 within the at least one alternating stack (32, 46) except the one of the electrically conductive layers 46 is laterally spaced from the side-contact via structure 86 by a respective one of the annular dielectric spacers 82.

In one embodiment, each of the annular dielectric spacers 82 comprises a respective outer cylindrical sidewall that is laterally offset outward from a respective inner cylindrical sidewall by a respective lateral offset distance that is independent of an azimuthal angle from a vertical axis VA passing through a geometrical center GC of the side-contact via structure 86; and all lateral offset distances of the annular dielectric spacers 82 are the same.

In one embodiment, each of the insulating layers 32 within the at least one alternating stack (32, 46) comprises a respective cylindrical sidewall that contacts the side-contact via structure 86.

In one embodiment, the memory device comprises backside blocking dielectric layers 44 located between each vertically neighboring pair of an insulating layer 32 and an electrically conductive layer 46 within the at least one alternating stack (32, 46), wherein the side-contact via structure 86 is in contact with two cylindrical surface segments of the backside blocking dielectric layers 44.

In one embodiment, each of the electrically conductive layers 46 comprises a respective combination of a metallic barrier liner 46A and a metallic fill material portion 46B; and the side-contact via structure 86 is in contact with a metallic barrier liner 46A of the one of the electrically conductive layers 46, and is laterally spaced from a metallic fill material portion 46B of the one of the electrically conductive layers 46.

In one embodiment, the memory device comprises a vertical stack of annular dielectric spacers 82 laterally surrounding the side-contact via structure 86, wherein the side-contact via structure 86 is in contact with an inner cylindrical sidewall of each annular dielectric spacer 82 within the vertical stack of annular dielectric spacers 82.

In one embodiment, the memory device comprises additional side-contact via structures 86 vertically extending through each layer within the at least one alternating stack (32, 46) and contacting a sidewall of a respective electrically conductive layer 46 of the electrically conductive layers 46.

In one embodiment, the memory device further comprises at least one semiconductor source layer 110 located below the at least one alternating stack (32, 46), wherein: each of the vertical semiconductor channels 60 comprises an end portion that is electrically connected to the at least one semiconductor source layer 110; and the first sidewall-contact via structure is electrically isolated from the at least one semiconductor source layer 110 by a semiconductor oxide plate 120.

In one embodiment, the at least one semiconductor source layer 110 comprises a layer stack including a lower source-level material layer 112, a source contact layer 114 contacting each of the vertical semiconductor channels 60, and an upper source-level material layer 116.

In one embodiment, the at least one alternating stack (32, 46) comprises: a first alternating stack (132, 146) of first insulating layers 132 and first electrically conductive layers 146; and a second alternating stack (232, 246) of second insulating layers 232 and second electrically conductive layers 246, wherein: the first insulating layers 132 comprise a first subset of the insulating layers 32 of the at least one alternating stack (32, 46); the first electrically conductive layers 146 comprise a first subset of the electrically conductive layers 46 of the at least one alternating stack (32, 46); the second insulating layers 232 comprise a second subset of the insulating layers 32 of the at least one alternating stack (32, 46); and the second electrically conductive layers 246 comprise a second subset of the electrically conductive layers 46 of the at least one alternating stack (32, 46).

In one embodiment, the memory device comprises: a substrate 8 vertically spaced from the at least one alternating stack (32, 46); a peripheral circuitry 710 located on the substrate 8; lower-level metal interconnect structures 780 embedded within lower-level dielectric layers 760 and located over the peripheral circuitry 710; source-level material layers 110 located over the lower-level dielectric layers 760 and underlying the at least one alternating stack (32, 46); and upper-level metal interconnect structures 980 embedded within upper-level dielectric layers 960 and located over the at least one alternating stack (32, 46), wherein the upper-level metal interconnect structures 980 are electrically connected to the peripheral circuitry 710 through the lower-level metal interconnect structures 780.

The various embodiments of the present disclosure can be employed to provide side-contact via structures 86, that contact a respective electrically conductive layer 46 in a three-dimensional memory device including at least one alternating stack of insulating layers 32 and electrically conductive layers 46 without forming any stepped surfaces on the at least one alternating stack (32, 46). Elimination of stepped surfaces in the three-dimensional memory device can reduce the device area employed for the layer contact via structures, and can reduce the die area of the three-dimensional memory device. Furthermore, support pillar structures do not have to be formed at least under the ide-contact via structures 86. This can reduce the area of the memory device and reduce complexity. Furthermore, formation of a continuous dielectric spacer in the contact via cavities and a reactive ion etch of a horizontal bottom surface of such continuous spacer is omitted.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
at least one alternating stack of insulating layers and electrically conductive layers;
memory openings vertically extending through each layer within the at least one alternating stack;
memory opening fill structures located in the memory openings and comprising a respective vertical semiconductor channel and a respective vertical stack of memory elements; and
an electrically conductive side-contact via structure vertically extending through each layer within the at least one alternating stack and contacting a sidewall of one of the electrically conductive layers.

2. The memory device of claim 1, wherein an entirety of an interface between the side-contact via structure and the one of the electrically conductive layers is located within a cylindrical vertical plane.

3. The memory device of claim 1, further comprising a vertical stack of annular dielectric spacers laterally surrounding the side-contact via structure, wherein each electrically conductive layer within the at least one alternating stack except the one of the electrically conductive layers is laterally spaced from the side-contact via structure by a respective one of the annular dielectric spacers.

4. The memory device of claim 3, wherein:
each of the annular dielectric spacers comprises a respective outer cylindrical sidewall that is laterally offset outward from a respective inner cylindrical sidewall by a respective lateral offset distance that is independent of an azimuthal angle from a vertical axis passing through a geometrical center of the side-contact via structure; and
all lateral offset distances of the annular dielectric spacers are the same.

5. The memory device of claim 1, wherein each of the insulating layers within the at least one alternating stack comprises a respective cylindrical sidewall that contacts the side-contact via structure.

6. The memory device of claim 1, further comprising backside blocking dielectric layers located between each vertically neighboring pair of an insulating layer and an electrically conductive layer within the at least one alternating stack, wherein the side-contact via structure is in contact with two cylindrical surface segments of the backside blocking dielectric layers.

7. The memory device of claim 1, wherein:
each of the electrically conductive layers comprises a respective combination of a metallic barrier liner and a metallic fill material portion; and
the side-contact via structure is in contact with a metallic barrier liner of the one of the electrically conductive layers, and is laterally spaced from a metallic fill material portion of the one of the electrically conductive layers.

8. The memory device of claim 7, further comprising a vertical stack of annular dielectric spacers laterally surrounding the side-contact via structure, wherein the side-contact via structure is in contact with an inner cylindrical sidewall of each annular dielectric spacer within the vertical stack of annular dielectric spacers.

9. The memory device of claim 1, further comprising additional side-contact via structures vertically extending through each layer within the at least one alternating stack and contacting a sidewall of a respective electrically conductive layer of the electrically conductive layers.

10. The memory device of claim 1, further comprising at least one semiconductor source layer located below the alternating stack, wherein:
each of the vertical semiconductor channels comprises an end portion that is electrically connected to the at least one semiconductor source layer; and
the first sidewall-contact via structure is electrically isolated from the at least one semiconductor source layer by a semiconductor oxide plate.

11. The memory device of claim 10, wherein the at least one semiconductor source layer comprises a layer stack including a lower source-level material layer, a source contact layer contacting each of the vertical semiconductor channels, and an upper source-level material layer.

12. The memory device of claim 1, wherein the at least one alternating stack comprises:
a first alternating stack of first insulating layers and first electrically conductive layers; and
a second alternating stack of second insulating layers and second electrically conductive layers, wherein:
the first insulating layers comprise a first subset of the insulating layers of the at least one alternating stack;
the first electrically conductive layers comprise a first subset of the electrically conductive layers of the at least one alternating stack;
the second insulating layers comprise a second subset of the insulating layers of the at least one alternating stack; and
the second electrically conductive layers comprise a second subset of the electrically conductive layers of the at least one alternating stack.

13. The memory device of claim 1, further comprising:
a substrate vertically spaced from the at least one alternating stack;
a peripheral circuitry located on the substrate;
lower-level metal interconnect structures embedded within lower-level dielectric layers and located over the peripheral circuitry;
source-level material layers located over the lower-level dielectric layers and underlying the at least one alternating stack; and
upper-level metal interconnect structures embedded within upper-level dielectric layers and located over the at least one alternating stack, wherein the upper-level metal interconnect structures are electrically connected to the peripheral circuitry through the lower-level metal interconnect structures.

14. A method of forming a memory device, comprising:
forming at least one alternating stack of insulating layers and sacrificial material layers over a substrate;
forming memory openings through the at least one alternating stack;
forming memory opening fill structures in the memory openings, wherein each of the memory opening fill structures comprises a respective vertical stack of memory elements;
forming a combination of a contact opening and a vertical stack of annular dielectric spacers through the at least one alternating stack, wherein the vertical stack of annular dielectric spacers comprises an annular sacrificial spacer located adjacent to a first one of the sacrificial material layers, at least one upper annular dielectric spacer overlying the annular sacrificial spacer, and at least one lower annular dielectric spacer underlying the annular sacrificial spacer;
replacing the sacrificial material layers with electrically conductive layers;
removing the annular sacrificial spacer and inner portions of the annular dielectric spacers around the contact opening, wherein a cylindrical sidewall of a first electrically conductive layer is physically exposed in the contact opening; and
forming a side-contact via structure in the contact opening in contact with the cylindrical sidewall of the first electrically conductive layer, wherein the side-contact via structure is laterally spaced from and is electrically isolated from a remainder of the electrically conductive layers other than the first electrically conductive layer by remaining portions of the vertical stack of annular dielectric spacers.

15. The method of claim 14, further comprising:
forming an in-process contact opening through the at least one alternating stack, wherein the in-process contact opening vertically extends through a first subset of layers within the alternating stack;
forming a first subset of the annular dielectric spacers by replacing proximal portions of the sacrificial material layers with dielectric material portions around the in-process contact openings: and
vertically extending the in-process contact opening downward through an underlying insulating layer and an underlying spacer material layer within the at least one alternating stack underneath a bottom surface of the in-process contact opening.

16. The method of claim 15, wherein the annular sacrificial spacer is formed on a remaining portion of the underlying sacrificial material layer after vertically extending the in-process contact opening.

17. The method of claim 16, wherein:
the sacrificial material layers comprise silicon nitride layers; and
the annular sacrificial spacer is formed by oxidation of a tubular surface portion of the first sacrificial material layer exposed in the in-process contact opening.

18. The method of claim 16, further comprising:
vertically extending the in-process contact opening further downward after formation of the annular sacrificial spacer such that the in-process contact opening vertically extends through each layer within the at least one alternating stack to form the contact opening; and
forming a second subset of the annular dielectric spacers by replacing proximal portions of a subset of the sacrificial material layers that underlie the annular sacrificial spacer with additional dielectric material portions after formation of the contact opening.

19. The method of claim 14, further comprising:
forming a semiconductor source layer over the substrate and below the at least one alternating stack; and
converting a surface portion of the semiconductor source layer exposed in the contact opening into a semiconductor oxide plate, wherein the side-contact via structure is electrically isolated from the semiconductor source layer by the semiconductor oxide plate.

20. The method of claim 14, further comprising forming in-process source-level material layers over the substrate, wherein:
the at least one alternating stack is formed over the in-process source-level material layers;
the in-process source-level material layers comprise a lower source-level semiconductor layer, a source-level sacrificial layer, and an upper source-level semiconductor layer;
the memory openings are formed through the source-level sacrificial layer; and
the source-level sacrificial layer is replaced with a source contact layer after formation of the memory opening fill structures.
